(19) United States
(12) Patent Application Publication
(10) Pub. No.: US 2026/0090213 A1
(43) Pub. Date: Mar. 26, 2026

(54) DISPLAY DEVICE AND ELECTRONIC DEVICE INCLUDING THE SAME

(71) Applicant: Samsung Display Co., Ltd., Yongin-Si (KR)

(72) Inventors: Chan Young KIM, Yongin-si (KR); Jin Su LEE, Yongin-si (KR); Seong Yong HWANG, Yongin-si (KR); Sang Woo KANG, Yongin-si (KR); Choong Youl IM, Yongin-si (KR); Ha Seok JEON, Yongin-si (KR); Seong Min CHO, Yongin-si (KR)

(21) Appl. No.: 19/312,743

(22) Filed: Aug. 28, 2025

(30) Foreign Application Priority Data
Sep. 26, 2024 (KR) 10-2024-0131043

(51) Int. Cl. H10K 59/122; H10K 59/80

(52) U.S. Cl. CPC H10K 59/122; H10K 59/80515

(57) ABSTRACT

A display device may include first, second, and third anode electrodes, a pixel defining layer including first, second, and third pixel openings disposed on the first, the second, and the third anode electrodes, each having a circular shape and extending to portions of the first to third anode electrodes, respectively. emission layers are disposed on the first to third anode electrodes in the first to third pixel openings, a cathode electrode covers the pixel defining layer and the first to third emission layers, and a light blocking layer is disposed on the cathode electrode and includes circular openings. The third anode electrode may include a flat portion and an inclined portion. Centers of the first to third pixel openings coincide with centers of the first to third openings. A radius of the third opening may be less than a radius of the third pixel opening.

### CROSS-REFERENCE TO RELATED APPLICATION(S)

The present application claims priority to Korean patent application number 10-2024-0131043 filed on Sep. 26, 2024, the entire disclosure of which is incorporated herein in its entirety by reference.

### BACKGROUND

### Field of Invention

Various embodiments of the present disclosure relate to a display device and an electronic device including the display device.

### Description of Related Art

With the development of information technology, the importance of display devices, which serve as a connection medium between a user and information, has grown. To better fulfill its function as the connection medium, the use of display devices such as organic light emitting display devices is increasing.

### SUMMARY

Various embodiments of the present disclosure are directed to a display device with enhanced design flexibility and improved light output efficiency.

An embodiment of the present disclosure may provide a display device, including: a first, a second, and a third anode electrodes spaced apart from one another; a pixel defining layer including a first, a second, and a third pixel openings disposed on the first, the second, and the third anode electrodes, each of the first, the second, and the third pixel openings having a circular shape in a plan view and extending to portions of the first, the second, and the third anode electrodes, respectively; a first, a second, and a third emission layers disposed on the first, the second, and the third anode electrodes in the first, the second, and the third pixel openings, respectively; a cathode electrode covering the pixel defining layer and the first, the second, and the third emission layers; and a light blocking layer disposed on the cathode electrode and including a first opening, a second opening, and a third opening each having a circular shape in a plan view. The third anode electrode may include, in an area overlapping the third pixel opening, a flat portion and an inclined portion around the flat portion. Centers of the first pixel opening, the second pixel opening, and the third pixel opening may coincide with centers of the first opening, the second opening, and the third openings, respectively. A radius of the third opening may be smaller than a radius of the third pixel opening.

In an embodiment, a radius of the first opening may be greater than a radius of the first pixel opening. A radius of the second opening may be greater than a radius of the second pixel opening.

In an embodiment, the radius of the third pixel opening may be greater than a radius of the first pixel opening and a radius of the second pixel opening.

In an embodiment, a radius of the first pixel opening may be greater than a radius of the second pixel opening.

In an embodiment, a difference between a radius of the first opening and a radius of the first pixel opening may be equal to a difference between a radius of the second opening and a radius of the second pixel opening.

In an embodiment, in a cross-sectional view, an acute angle formed by an upper surface of the inclined portion with respect to a plane parallel to an upper surface of the flat portion may be about 15 degrees or more and about 45 degrees or less.

In an embodiment, in a sectional view, a distance in a thickness direction between an upper surface of the third anode electrode overlapping a flat surface of the pixel defining layer and an upper surface of the flat portion may be about 0.5 micrometers or more and about 3 micrometers or less.

In an embodiment, in a cross-sectional view, an orthogonal projection of an edge of the third opening in a thickness direction may be positioned on the inclined portion.

In an embodiment, the display device may further include: a first color filter disposed in the first opening; a second color filter disposed in the second opening; and a third color filter disposed in the third opening.

An embodiment of the present disclosure may provide a display device, including: a first anode electrode including a first flat portion and a first inclined portion surrounding the first flat portion; a second anode electrode including a second flat portion and a second inclined portion surrounding the second flat portion; a third anode electrode including a third flat portion and a third inclined portion surrounding the third flat portion; a pixel defining layer including a first pixel opening extending to the first flat portion and the first inclined portion and having a circular shape in a plan view, a second pixel opening extending to the second flat portion and the second inclined portion and having a circular shape in a plan view, and a third pixel opening extending the third flat portion and the third inclined portion and having a circular shape in a plan view; first, second, and third emission layers disposed on the first, the second, and the third anode electrodes in the first, the second, and the third pixel openings, respectively; a cathode electrode covering the pixel defining layer and the first, the second, and the third emission layers; and a light blocking layer disposed on the cathode electrode, and including a first opening, a second opening, and a third opening each having a circular shape in a plan view. Centers of the first, the second, and the third pixel openings may coincide with centers of the first opening, the second opening, and the third opening, respectively.

In an embodiment, a radius of the first opening may be less than a radius of the first pixel opening in a plan view. A radius of the second opening may be less than a radius of the second pixel opening. A radius of the third opening may be less than a radius of the third pixel opening.

In an embodiment, in a plan view, a first difference between a radius of the first pixel opening and a radius of the first opening, a second difference between a radius of the second pixel opening and a radius of the second opening, and a third difference between the third pixel opening and a radius of the third opening may differ from one another.

In an embodiment, in a plan view, a radius of the third pixel opening may be greater than a radius of the first pixel opening and a radius of the second pixel opening.

In an embodiment, a radius of the first pixel opening may be greater than a radius of the second pixel opening.

In an embodiment, in a cross-sectional view, an orthogonal projection of an edge of the first opening in a thickness direction may be positioned on the first inclined portion. In a cross-sectional view, an orthogonal projection of an edge of the second opening in the thickness direction may be positioned on the second inclined portion. In a cross-sectional view, an orthogonal projection of an edge of the third opening in the thickness direction may be positioned on the third inclined portion.

In an embodiment, in a cross-sectional view, a first acute angle between an upper surface of the first inclined portion and a plane parallel to an upper surface of the first flat portion, a second acute angle between an upper surface of the second inclined portion and a plane parallel to an upper surface of the second flat portion, and a third acute angle between an upper surface of the third inclined portion and to a plane parallel to an upper surface of the third flat portion may each be about 15 degrees or more and about 45 degrees or less.

In an embodiment, in a cross-sectional view, the first acute angle between an upper surface of the first inclined portion with, the second acute angle, and the third acute angle may differ from one another.

In an embodiment, in a cross-sectional view, each of a first distance in a thickness direction between an upper surface of the first anode electrode overlapping the pixel defining layer and an upper surface of the first flat portion, a second distance in the thickness direction between an upper surface of the second anode electrode overlapping the pixel defining layer and an upper surface of the second flat portion, and a third distance in the thickness direction between an upper surface of the third anode electrode overlapping the pixel defining layer and an upper surface of the third flat portion may be at least about 0.5 micrometers and no more than and about 3 micrometers.

In an embodiment, in a cross-sectional view, the first distance, the second distance, and the third distance may differ from one another.

An embodiment of the present disclosure may provide an electronic device, including: a display device to display an image. The display device may include: a first, a second, and a third anode electrodes spaced apart from one another; a pixel defining layer including a first, a second, and a third pixel openings extending to portions of the first, the second, and the third anode electrodes, respectively; a first, a second, and a third emission layers disposed on the first, the second, and the third anode electrodes in the first, the second, and the third pixel openings, respectively; a cathode electrode covering the pixel defining layer and the first, the second, and the third emission layers; and a light blocking layer disposed on the cathode electrode, and including a first opening, a second opening, and a third opening each having a circular shape in a plan view. The third anode electrode includes, in an area overlapping the third pixel opening, a flat portion and an inclined portion around the flat portion. Centers of the first pixel opening, the second pixel opening, and the third pixel opening may coincide with centers of the first opening, the second opening, and the third opening, respectively. The radius of the third opening may be smaller than a radius of the third pixel opening.

### BRIEF DESCRIPTION OF THE DRAWINGS

FIG. 1 is a block diagram for describing a display device in accordance with embodiments of the present disclosure.

FIG. 2 is a block diagram for describing any one sub-pixel among sub-pixels included in a display device of FIG. 1.

FIG. 3 is a plan view for describing a display panel that constitutes the display device of FIG. 1.

FIG. 4 is a sectional view for describing an embodiment of the display panel of FIG. 3.

FIG. 5 is a sectional view for describing another embodiment of the display panel of FIG. 3.

FIGS. 6 and 7 are plan views for describing an embodiment of any one of pixels included in the display panel of FIG. 3.

FIG. 8 is a sectional view taken along line I1-I1′ of FIG. 7.

FIG. 9 is a sectional view taken along line I2-I2′ of FIG. 7.

FIG. 10 is an enlarged plan view illustrating a third sub-pixel area of FIG. 9.

FIGS. 11 and 12 are plan views for describing another embodiment of any one of the pixels included in the display panel of FIG. 3.

FIG. 13 is a sectional view taken along line I3-I3′ of FIG. 12.

FIG. 14 is an enlarged plan view illustrating a first sub-pixel area of FIG. 12.

FIG. 15 is an enlarged plan view illustrating a 2-1-th sub-pixel area of FIG. 12.

FIG. 16 is a sectional view taken along line I4-I4′ of FIG. 12.

FIG. 17 is an enlarged sectional view illustrating a 2-2-th sub-pixel area of FIG. 16.

FIG. 18 is an enlarged sectional view illustrating a third sub-pixel area of FIG. 16.

FIG. 19 is a block diagram of an electronic device according to an embodiment.

FIG. 20 shows schematic views of various embodiments of an electronic device.

### DETAILED DESCRIPTION

Hereinafter, an embodiment of the present invention will be described in detail with reference to the attached drawings. In the following description, only parts required for understanding of operations in accordance with the present disclosure will be described, and explanation of the other parts will be omitted. Accordingly, the present disclosure is not limited to the embodiments set forth herein and may be embodied in variations. Rather, these embodiments are provided so that the present disclosure will be thorough and complete, and will fully convey the technical spirit of the disclosure to those skilled in the art.

It will be understood that when an element is referred to as being “coupled” or “connected” to another element, it can be directly coupled or connected to the other element or indirectly coupled or connected to the other element with intervening elements therebetween. The terminology used herein is for the purpose of describing particular embodiments only and is not intended to be limiting. In the specification, when an element is referred to as “comprising” or “including” a component, it does not preclude another component but may further include other components unless the context clearly indicates otherwise. “at least one of X, Y, and Z” and “at least one selected from the array consisting of X, Y, and Z” may be construed as X only, Y only, Z only, or any combination of two or more of X, Y, and Z (for instance, XYZ, XYY, YZ, and ZZ). As used herein, the term “and/or” can include any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure. Furthermore, there could be a plurality of “first” elements and/or a plurality of “second” elements.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element or feature's relationship to another element(s) or feature(s), as illustrated in the drawings. Spatially relative terms are intended to encompass different orientations of an apparatus in use, operation, and/or manufacture in addition to the orientation depicted in the drawings. For example, if the device in the drawings is turned upside down, elements described as “below” or “beneath” other elements or features would then be oriented “above” the other elements or features. Thus, the term “below” can encompass both an orientation of above and below. Furthermore, the device may be otherwise oriented (e.g., rotated 90 degrees or at other orientations), and, as such, the spatially relative descriptors used herein interpreted accordingly.

Various embodiments will be described with reference to diagrams illustrating idealized embodiments. As such, variations from the shapes of the illustrations as a result, for example, of manufacturing techniques and/or tolerances, are to be expected. Therefore, embodiments disclosed herein should not be construed as limited to the specific shapes of regions as illustrated, but are to include deviations in shapes that result from, for instance, manufacturing. As such, the shapes illustrated in the drawings may not illustrate the exact shapes of regions of a device, and, as such, are not intended to be limiting.

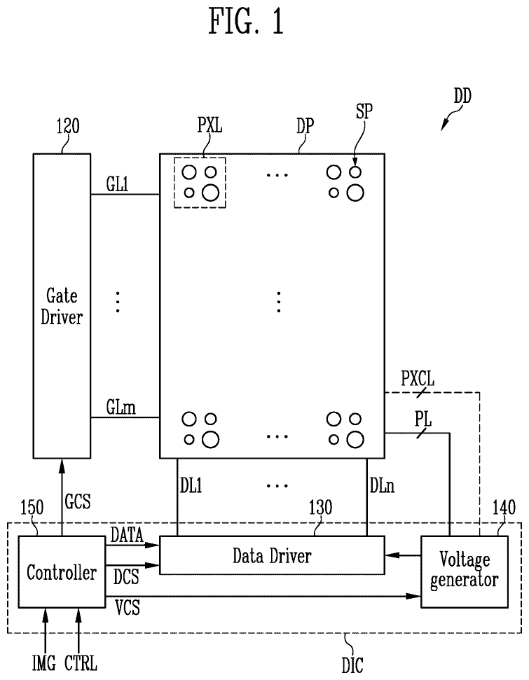

FIG. 1 is a block diagram for describing a display device DD in accordance with embodiments of the present disclosure.

Referring to FIG. 1, the display device DD may include a display panel DP, a gate driver 120, a data driver 130, a voltage generator 140, and a controller 150.

The display panel DP may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

The sub-pixels SP may generate light in two or more colors. For example, each of the sub-pixels SP may generate light in a color such as red, green, blue, cyan, magenta, or yellow.

Two or more sub-pixels among the sub-pixels SP may form one pixel PXL. For example, the pixel PXL may include fourth sub-pixels, as illustrated in FIG. 1. The pixel PXL may emit light of various colors and various luminances depending on the combination of light emitted from the sub-pixels included in the pixel PXL.

The gate driver 120 may be connected to sub-pixels SP arranged in a row direction through first to m-th gate lines GL1 to GLm. The gate driver 120 may output gate signals to the first to m-th gate lines GL1 to GLm in response to a gate control signal GCS. In embodiments, the gate control signal GCS may include a start signal instructing each frame to start, a horizontal synchronization signal, and the like.

The gate driver 120 may be disposed on a first side of the display panel DP. However, the embodiments are not limited to the aforementioned example. For example, the gate driver 120 may be divided into two or more drivers that are physically and/or logically distinguished from one another. The drivers may be disposed on the first side of the display panel DP and a second side thereof opposite to the first side. As such, the gate driver 120 may be disposed around the display panel DP in various forms depending on the embodiments.

The data driver 130 may be connected to sub-pixels SP arranged in a column direction through the first to n-th data lines DL1 to DLn. The data driver 130 may receive image data DATA and a data control signal DCS from the controller 150. The data driver 130 may operate in response to the data control signal DCS. In embodiments, the data control signal DCS may include a source start signal, a source shift clock, a source output enable signal, and the like.

The data driver 130 may receive voltages from the voltage generator 140. The data driver 130 may apply, using received voltages, data signals having grayscale voltages corresponding to the image data DATA to the first to n-th data lines DL1 to DLn. When a gate signal is applied to each of the first to m-th gate lines GL1 to GLm, data signals corresponding to the image data DATA may be applied to the data lines DL1 to DLn. Hence, the sub-pixels SP may generate light corresponding to the data signals, and the display panel DP may display an image.

In embodiments, the gate driver 120 and the data driver 130 may include complementary metal-oxide semiconductor (CMOS) circuit elements.

The voltage generator 140 may operate in response to a voltage control signal VCS provided from the controller 150. The voltage generator 140 is configured to generate a plurality of voltages and provide the generated voltages to components of the display device DD such as the gate driver 120, the data driver 130, and the controller 150. The voltage generator 140 may receive an input voltage from an external device of the display device DD and generate a plurality of voltages by regulating the received voltage.

The voltage generator 140 may generate a first power voltage and a second power voltage. The generated first and second power voltages may be provided to the sub-pixels SP through power lines PL. In another embodiment, at least one of the first and second power voltages may be provided from an external device of the display device DD.

In addition, the voltage generator 140 may provide various voltages and/or signals. For example, the voltage generator 140 may provide one or more initialization voltages to be applied to the sub-pixels SP. For example, during a sensing operation for sensing electrical characteristics of transistors and/or light emitting elements of the sub-pixels SP, a certain reference voltage may be applied to each of the first to n-th data lines DL1 to DLn. The voltage generator 140 may generate the reference voltage and transmit the reference voltage to the data driver 130. For example, during a display operation for displaying an image on the display panel DP, common pixel control signals may be applied to the sub-pixels SP, and the voltage generator 140 may generate the pixel control signals. In embodiments, the voltage generator 140 may provide pixel control signals to the sub-pixels SP through pixel control lines PXCL. Although in FIG. 1 there is illustrated the case where the pixel control lines PXCL are connected between the voltage generator 140 and the display panel DP, embodiments are not limited thereto. For example, the pixel control lines PXCL may be connected between the gate driver 120 and the display panel DP. In this case, the pixel control signals may be transmitted from the voltage generator 140 to the pixel control lines PXCL through the gate driver 120.

The controller 150 may control overall operations of the display device DD. The controller 150 may receive input image data IMG and a corresponding control signal CTRL from an external device. The controller 150 may provide a gate control signal GCS, a data control signal DCS, and a voltage control signal VCS, in response to the control signal CTRL.

The controller 150 may convert the input image data IMG to be suitable for the display device DD or the display panel DP and then output image data DATA. In embodiments, the controller 150 may align the input image data IMG to be suitable for the sub-pixels SP on a row basis and then output the image data DATA.

Two or more components of the data driver 130, the voltage generator 140, and the controller 150 may be mounted on a single integrated circuit. As illustrated in FIG. 1, the data driver 130, the voltage generator 140, and the controller 150 may be included in a driver integrated circuit DIC. In this case, the data driver 130, the voltage generator 140, and the controller 150 may be components that are functionally separated from one another in the single driver integrated circuit DIC. In other embodiments, at least one of the data driver 130, the voltage generator 140, and the controller 150 may be provided as a component that is separate from the driver integrated circuit DIC.

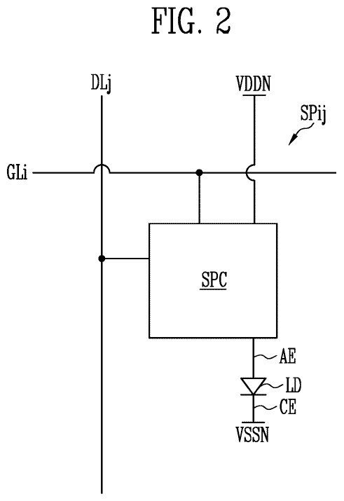

FIG. 2 is a block diagram for describing any one sub-pixel among the sub-pixels SP included in the display device DD of FIG. 1. In FIG. 2, there is illustrated a sub-pixel SPij disposed on an i-th row (where i is an integer identical to or greater than 1 and identical to or less than m) and a j-th column (where j is an integer identical to or greater than 1 and identical to or less than n) among the sub-pixels SP of FIG. 1.

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN may be connected to one of the power lines PL of FIG. 1 to receive a first power voltage. The second power voltage node VSSN may be connected to another one of the power lines PL of FIG. 1 to receive a second power voltage. The first power voltage may have a voltage level higher than the second power voltage.

The light emitting element LD may be connected between an anode electrode AE and a cathode electrode CE. The anode electrode AE may be connected to the first power voltage node VDDN through the sub-pixel circuit SPC. For example, the anode electrode AE may be connected to the first power voltage node VDDN through one or more transistors included in the sub-pixel circuit SPC. The cathode electrode CE may be connected to the second power voltage node VSSN. The light emitting element LD is configured to emit light based on current flowing from the anode electrode AE to the cathode electrode CE.

The sub-pixel circuit SPC may be connected both to the i-gate line GLi among the first to m-th gate lines GL1 to GLm of FIG. 1 and to the j-th data line DLj among the first to n-th data lines DL1 to DLn of FIG. 1. In response to a gate signal received through the i-th gate line GLi, the sub-pixel circuit SPC may control the light emitting element LD to emit light based on a data signal received through the j-th data line DLj. In embodiments, the sub-pixel circuit SPC may be further connected to the pixel control lines PXCL of FIG. 1. In this case, the sub-pixel circuit SPC may further control the light emitting element LD in response to pixel control signals received through the pixel control lines PXCL.

For the sake of the aforementioned operations, the sub-pixel circuit SPC may include circuit elements, for example, transistors and one or more capacitors.

The transistors of the sub-pixel circuit SPC may include P-type transistors and/or N-type transistors. In embodiments, the transistors of the sub-pixel circuit SPC may include a metal oxide semiconductor field effect transistor (MOSFET). In embodiments, the transistors of the sub-pixel circuit SPC may include an amorphous silicon semiconductor, a monocrystalline silicon semiconductor, a polycrystalline silicon semiconductor, an oxide semiconductor, or the like.

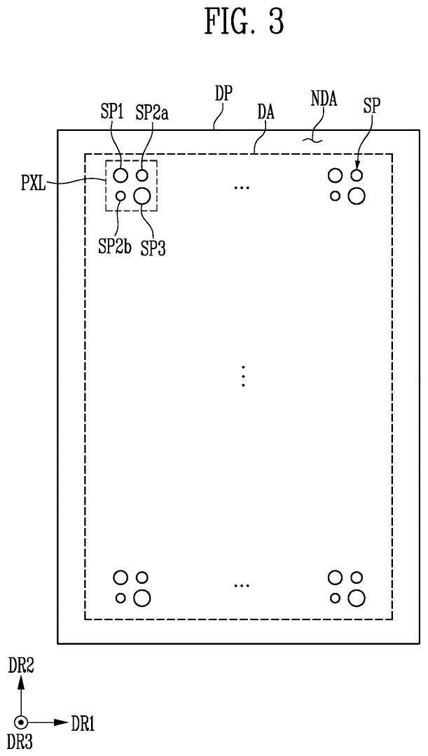

FIG. 3 is a plan view for describing the display panel DP that constitutes the display device DD of FIG. 1.

Referring to FIG. 3, the display panel DP may include a display area DA and a non-display area NDA. The display panel DP may display an image through the display area DA. The non-display area NDA may be disposed around the display area DA.

The display panel DP may include sub-pixels SP disposed in the display area DA. The sub-pixels SP may be arranged in a first direction DR1 and a second direction DR2 intersecting with the first direction DR1. For example, the sub-pixels SP may be arranged in a matrix pattern in the first direction DR1 and the second direction DR2. For example, the sub-pixels SP may be arranged in a zigzag pattern in the first direction DR1 and the second direction DR2. The arrangement of the sub-pixels SP may be changed depending on embodiments. The first direction DR1 may refer to a row direction, and the second direction DR2 may refer to a column direction.

Two or more sub-pixels among the sub-pixels SP may form one pixel PXL. Although FIG. 3 illustrates that the pixel PXL includes four sub-pixels SP1, SP2a, SP2b, and SP3, embodiments are not limited thereto. For example, the pixel PXL may include two sub-pixels. Hereinafter, for convenience in explanation, it is assumed that the pixel PXL includes a first sub-pixel SP1, a 2-1-th sub-pixel SP2a, a 2-2-th sub-pixel SP2b, and a third sub-pixel SP3. As used herein, the 2-1-th sub-pixel SP2a and the 2-2-th sub-pixel SP2b are collectively referred to as the “second sub-pixel SP2.” The parts X of the second sub-pixel SP2 will also be collectively referred to as “a second” X, with the understanding that there may be more than one “second” X.

Each of the first sub-pixel SP1, the 2-1-th sub-pixel SP2a, the 2-2-th sub-pixel SP2b, and the third sub-pixel SP3 may generate light of one of various colors such as red, green, blue, cyan, magenta, and yellow. Hereinafter, for clear and concise description, it is assumed that the first sub-pixel SP1 is configured to generate light in red, each of the 2-1-th sub-pixel SP2a and the 2-2-th sub-pixel SP2b is configured to generate light in green, and the third sub-pixel SP3 is configured to generate light in blue.

Each of the first sub-pixel SP1, the 2-1-th sub-pixel SP2a, the 2-2-th sub-pixel SP2b, and the third sub-pixel SP3 may include at least one light emitting element configured to generate light. In embodiments, the light emitting elements of the first sub-pixel SP1, the 2-1-th sub-pixel SP2a, the 2-2-th sub-pixel SP2b, and the third sub-pixel SP3 may generate light of different colors. For example, the light emitting elements of the first sub-pixel SP1, the 2-1-th sub-pixel SP2a, the 2-2-th sub-pixel SP2b, and the third sub-pixel SP3 may respectively generate red light, green light, green light, and blue light.

As the display panel DP, for example, a self-emissive display panel such as an organic light emitting display (OLED) panel using an organic light emitting diode as a light emitting element may be used.

Components for controlling the sub-pixels SP may be disposed in the non-display area NDA. Lines connected to the sub-pixels SP, for example, the first to m-th gate lines GL1 to GLm, the first to n-th data lines DL1 to DLn, the power lines PL, and the pixel control lines PXCL of FIG. 1, may be disposed in the non-display area NDA.

At least one of the gate driver 120, the data driver 130, the voltage generator 140, and the controller 150 of FIG. 1 may be disposed in the non-display area NDA of the display panel DP. In embodiments, the gate driver 120 may be disposed in the non-display area NDA. In this case, the data driver 130, the voltage generator 140, and the controller 150 may be implemented as the driver integrated circuit DIC of FIG. 1 that is separate from the display panel DP. The driver integrated circuit DIC may be connected to the lines disposed in the non-display area NDA. In other embodiments, the gate driver 120 along with the data driver 130, the voltage generator 140, and the controller 150 may be implemented as a single integrated circuit that is separate from the display panel DP.

In embodiments, the display area DA may have various shapes. The display area DA may have a closed-loop shape, including linear and/or curved sides. For example, the display area DA may have shapes such as polygons, circles, semicircles, ellipses, and the like.

In embodiments, the display panel DP may have a planar display surface. In embodiments, the display panel DP may have a display surface that is at least partially rounded. In embodiments, the display panel DP is bendable, foldable, or rollable. In the aforementioned cases, the display panel DP and/or a substrate of the display panel DP may include materials having flexible properties.

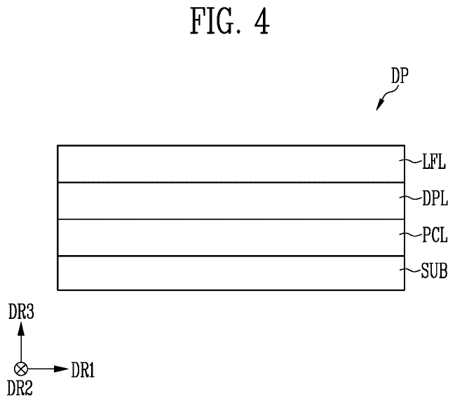

FIG. 4 is a sectional view for describing an embodiment of the display panel of FIG. 3.

Referring to FIG. 4, the display panel DP may include a substrate SUB, and a pixel circuit layer PCL, a display element layer DPL, and a light functional layer LFL that are sequentially stacked on the substrate SUB in a third direction DR3 intersecting with the first and second directions DR1 and DR2.

The substrate SUB may be made of insulating material such as glass or resin. For example, the substrate SUB may include a glass substrate. In another example, the substrate SUB may include a polyimide (PI) substrate. In another example, the substrate SUB may include a silicon wafer substrate formed through a semiconductor process.

In embodiments, the substrate SUB may be made of material having flexibility so as to be bendable or foldable, and may have a single-layer structure or a multilayer structure. For instance, examples of the material having flexibility may include at least one of the following: polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, the embodiments are not limited thereto.

The pixel circuit layer PCL may be disposed on the substrate SUB. The pixel circuit layer PCL may include insulating layers, and semiconductor patterns and conductive patterns disposed between the insulating layers. The conductive patterns of the pixel circuit layer PCL may function as circuit elements, lines, or the like.

The circuit elements of the pixel circuit layer PCL may form the sub-pixel circuit SPC of each of the sub-pixels SP of FIG. 3. In other words, the circuit elements of the pixel circuit layer PCL may be provided as transistors and one or more capacitors of the sub-pixel circuit SPC.

The lines of the pixel circuit layer PCL may include lines connected to the sub-pixels SP. The lines of the pixel circuit layer PCL may include various signal lines and/or voltage lines needed to drive the display element layer DPL.

The display element layer DPL may be disposed on the pixel circuit layer PCL. The display element layer DPL may include the light emitting elements of the sub-pixels SP.

The light functional layer LFL may be disposed on the display element layer DPL. The light functional layer LFL may include light conversion patterns having color conversion particles and/or scattering particles. For example, the color conversion particles may include quantum dots. The quantum dots may convert the wavelength (or color) of light emitted from the display element layer DPL. The light functional layer LFL may further include light scattering patterns having scattering particles. In embodiments, the light conversion patterns and the light scattering patterns may be omitted.

The light functional layer LFL may further include a color filter layer including color filters. Each of the color filters may selectively transmit light of a specific wavelength (or specific color). In embodiments, the color filter layer may be omitted.

A window may be provided on the light functional layer LFL to protect an exposed surface (or upper surface) of the display panel DP. The window may protect the display panel DP from an external impact. The window may be connected to the light functional layer LFL by an optically transparent adhesive (or bonding) agent. The window may have a multilayer structure selected from among a glass substrate, a plastic film, and a plastic substrate. The multilayer structure may be formed through a successive process or an adhesion process using an adhesive layer. The entirety or portion of the window may have flexibility.

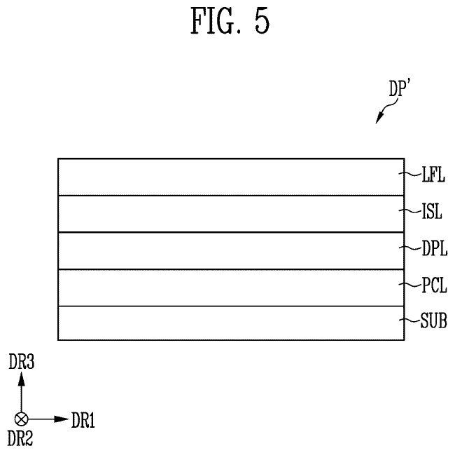

FIG. 5 is a sectional view for describing another embodiment of the display panel of FIG. 3.

Referring to FIG. 5, a display panel DP′ may include a substrate SUB, a pixel circuit layer PCL, a display element layer DPL, an input sensing layer ISL, and a light functional layer LFL. The substrate SUB, the pixel circuit layer PCL, the display element layer DPL, and the light functional layer LFL may be configured in a manner substantially identical (or similar) to the substrate SUB, the pixel circuit layer PCL, the display element layer DPL, and the light functional layer LFL that have been described with reference to FIG. 4. Therefore, redundant explanations will be omitted.

The input sensing layer ISL may sense a user input on an upper surface (or display surface) of the display panel DP′. The input sensing layer ISL may include components suitable for sensing an external object such as the hand of the user, a pen, or the like. For example, the input sensing layer ISL may include touch electrodes.

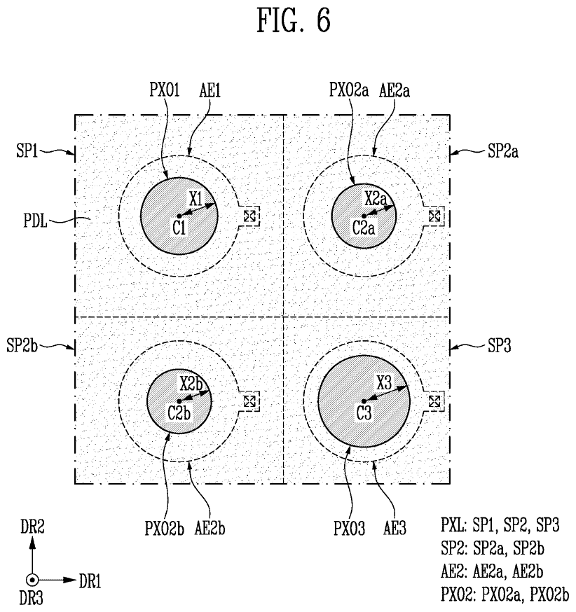

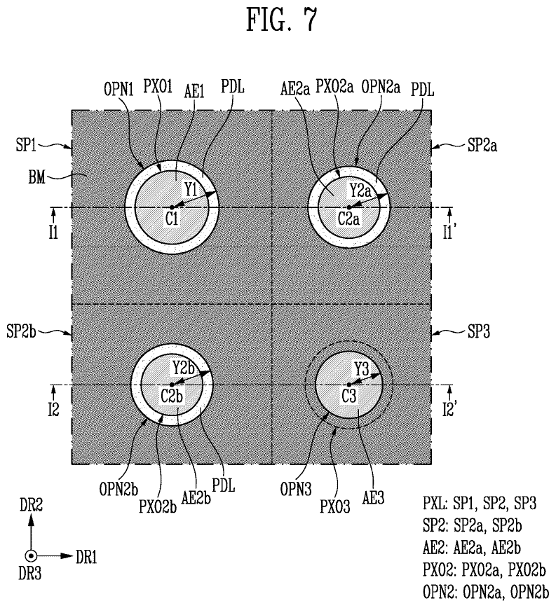

FIGS. 6 and 7 are plan views for describing an embodiment of any one of the pixels included in the display panel of FIG. 3.

Referring to FIG. 6, the pixel PXL may include first to third sub-pixels SP1, SP2, and SP3. The first sub-pixel SP1 is configured to generate light in red, the second color pixel SP2 is configured to generate light in green, and the third sub-pixel SP3 is configured to generate light in blue.

The first sub-pixel SP1 may include a first anode electrode AE1. The first anode electrode AE1 may be provided as the anode electrode AE (refer to FIG. 2) connected to the sub-pixel circuit SPC (refer to FIG. 2) of the first sub-pixel SP1.

The second sub-pixel SP2 may include a second anode electrode AE2 spaced apart from the first anode electrode AE1. The second anode electrode AE2 may be provided as the anode electrode AE connected to the sub-pixel circuit SPC of the second sub-pixel SP2.

In an embodiment, the second sub-pixel SP2 may include a 2-1-th sub-pixel SP2a and a 2-2-th sub-pixel SP2b. The 2-1-th sub-pixel SP2a may include a 2-1-th anode electrode AE2a. The 2-1-th anode electrode AE2a may be provided as the anode electrode AE connected to the sub-pixel circuit SPC of the 2-1-th sub-pixel SP2a. The 2-2-th sub-pixel SP2b may include a 2-2-th anode electrode AE2b spaced apart from the 2-1-th anode electrode AE2a. The 2-2-th anode electrode AE2b may be provided as the anode electrode AE connected to the sub-pixel circuit SPC of the 2-2-th sub-pixel SP2b.

The third sub-pixel SP3 may include a third anode electrode AE3 spaced apart from the first and second anode electrodes AE1 and AE2. The third anode electrode AE3 may be provided as the anode electrode AE connected to the sub-pixel circuit SPC of the third sub-pixel SP3.

The pixel PXL may include a pixel defining layer PDL. The pixel defining layer PDL may include first to third pixel openings PXO1, PXO2, and PXO3 that respectively expose portions of the first to third anode electrodes AE1, AE2, and AE3.

The first pixel opening PXO1 may expose a portion of the first anode electrode AE1. The first pixel opening PXO1 may be circular in a plan view. In this case, a center of the first pixel opening PXO1 (i.e., the center of the circle) may be a first center C1. A radius of the first pixel opening PXO1 (i.e., the radius of the circuit) may be a first pixel radius X1.

The second pixel opening PXO2 may include a 2-1-th pixel opening PXO2a and a 2-2-th pixel opening PXO2b.

The 2-1-th pixel opening PXO2a may expose a portion of the 2-1-th anode electrode AE2a. The 2-1-th pixel opening PXO2a may be circular in a plan view. In this case, a center of the 2-1-th pixel opening PXO2a may be a 2-1-th center C2a. A radius of the 2-1-th pixel opening PXO2a may be a 2-1-th pixel radius X2a.

The 2-2-th pixel opening PXO2b may expose a portion of the 2-2-th anode electrode AE2b. The 2-2-th pixel opening PXO2b may be circular in a plan view. In this case, a center of the 2-2-th pixel opening PXO2b may be a 2-2-th center C2b. A radius of the 2-2-th pixel opening PXO2b may be a 2-2-th pixel radius X2b.

In an embodiment, the 2-1-th pixel radius X2a may be substantially the same as the 2-2-th pixel radius X2b.

The third pixel opening PXO3 may expose a portion of the third anode electrode AE3. The third pixel opening PXO3 may be circular in a plan view. In this case, a center of the third pixel opening PXO3 may be a third center C3. A radius of the third pixel opening PXO3 may be a third pixel radius X3.

In an embodiment, the third pixel radius X3 may be greater than each of the first pixel radius X1, the 2-1-th pixel radius X2a, and the 2-2-th pixel radius X2b. The first pixel radius X1 may be greater than the 2-1-th pixel radius X2a and the 2-2-th pixel radius X2b.

Referring to FIG. 7, the pixel PXL may include a light blocking layer BM disposed on the pixel defining layer PDL. The light blocking layer BM may include first to third openings OPN1, OPN2, and OPN3.

The first opening OPN1 may be circular in a plan view. In this case, a center of the first opening OPN1 may correspond to the first center C1 that is the center of the first pixel opening PXO1. A radius of the first opening OPN1 may be a first opening radius Y1. In an embodiment, the first opening radius Y1 may be greater than the first pixel radius X1.

The second opening OPN2 may include a 2-1-th opening OPN2a and a 2-2-th opening OPN2b.

The 2-1-th opening OPN2a may be circular in a plan view. In this case, a center of the 2-1-th opening OPN2a may correspond to the 2-1-th center C2a that is the center of the 2-1-th pixel opening PXO2a. A radius of the 2-1-th opening OPN2a may be a 2-1-th opening radius Y2a. In an embodiment, the 2-1-th opening radius Y2a may be greater than the 2-1-th pixel radius X2a.

The 2-2-th opening OPN2b may be circular in a plan view. In this case, a center of the 2-2-th opening OPN2b may correspond to the 2-2-th center C2b that is the center of the 2-2-th pixel opening PXO2b. A radius of the 2-2-th opening OPN2b may be a 2-2-th opening radius Y2b. In an embodiment, the 2-2-th opening radius Y2b may be greater than the 2-2-th pixel radius X2b.

The third opening OPN3 may be circular in a plan view. In this case, a center of the third opening OPN3 may correspond to the third center C3 that is the center of the third pixel opening PXO3. A radius of the third opening OPN3 may be a third opening radius Y3. In an embodiment, the third opening radius Y3 may be less than the third pixel radius X3.

In an embodiment, a difference between the first opening radius Y1 of the first opening OPN1 and the first pixel radius X1 of the first pixel opening PXO1 may be substantially the same as a difference between the 2-1-th opening radius Y2a of the 2-1-th opening OPN2a and the 2-1-th pixel radius X2a of the 2-1-th pixel opening PXO2a, and may be substantially the same as a difference between the 2-2-th opening radius Y2b of the 2-2-th opening OPN2b and the 2-2-th pixel radius X2b of the 2-2-th pixel opening PXO2b.

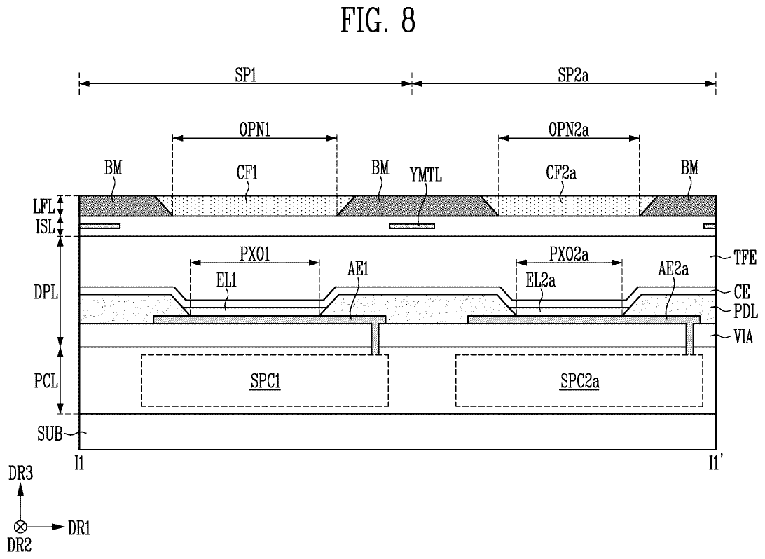

FIG. 8 is a sectional view taken along line I1-I1′ of FIG. 7. In FIG. 8, there are illustrated the first sub-pixel SP1 and the 2-1-th sub-pixel SP2a.

Referring to FIGS. 6 to 8, the pixel PXL may include the substrate SUB, the pixel circuit layer PCL, the display element layer DPL, the input sensing layer ISL, and the light functional layer LFL that are sequentially stacked in the third direction DR3.

The pixel circuit layer PCL may include a first sub-pixel circuit SPC1 and a 2-1-th sub-pixel circuit SPC2a. The first sub-pixel circuit SPC1 may be provided as the sub-pixel circuit SPC (refer to FIG. 2) of the first sub-pixel SP1. The 2-1-th sub-pixel circuit SPC2a may be provided as the sub-pixel circuit SPC (refer to FIG. 2) of the 2-1-th sub-pixel SP2a.

The display element layer DPL may include a via layer VIA, the first anode electrode AE1, the 2-1-th anode electrode AE2a, the pixel defining layer PDL, a first emission layer EL1, a 2-1-th emission layer EL2a, the cathode electrode CE, and an encapsulation layer TFE.

The via layer VIA may be disposed on the pixel circuit layer PCL. The via layer VIA may have a single-layer structure or multilayer structure including inorganic material and/or organic material. In an embodiment, in an area where the first sub-pixel SP1 and the 2-1-th sub-pixel SP2a are provided, an upper surface of the via layer VIA may be substantially flat.

The first anode electrode AE1 may be disposed on the via layer VIA. The first anode electrode AE1 may be connected to the first sub-pixel circuit SPC1 through a via hole that penetrates the via layer VIA and one or more insulating layers among the insulating layers that constitute the pixel circuit layer PCL. In an embodiment, an upper surface of the first anode electrode AE1 may be substantially flat.

The 2-1-th anode electrode AE2a may be disposed on the via layer VIA. The 2-1-th anode electrode AE2a may be connected to the 2-1-th sub-pixel circuit SPC2a through a via hole that penetrates the via layer VIA and one or more insulating layers among the insulating layers that constitute the pixel circuit layer PCL. In an embodiment, an upper surface of the 2-1-th anode electrode AE2a may be substantially flat.

The pixel defining layer PDL may be disposed on the via layer VIA, the first anode electrode AE1, and the 2-1-th anode electrode AE2a. The pixel defining layer PDL may include the first pixel opening PXO1 that exposes a portion of the first anode electrode AE1, and the 2-1-th pixel opening PXO2a that exposes a portion of the 2-1-th anode electrode AE2a. The pixel defining layer PDL may include light blocking material, and may function to prevent light mixing between adjacent sub-pixels. In embodiments, the pixel defining layer PDL may include organic material. For example, the pixel defining layer PDL may include organic insulating material made of material such as acryl resin, epoxy resin, phenol resin, polyamide resin, polyimide resin, or the like.

The first emission layer EL1 may be disposed on the first anode electrode AE1 in the first pixel opening PXO1. The first emission layer EL1 may include organic emission material formed to generate red light.

The 2-1-th emission layer EL2a may be disposed on the 2-1-th anode electrode AE2a in the 2-1-th pixel opening PXO2a. The 2-1-th emission layer EL2a may include organic emission material formed to generate green light.

The cathode electrode CE may cover the pixel defining layer PDL, the first emission layer EL1, and the 2-1-th emission layer EL2a. The cathode electrode CE may be electrically connected to the second power voltage node VSSN of FIG. 2. The cathode electrode CE may be configured to be substantially transparent or translucent to meet a certain light transmittance. For example, the cathode electrode CE may include at least one of various transparent conductive materials such as indium tin oxide (ITO), indium zinc oxide (IZO), zinc oxide (ZnO), indium gallium zinc oxide (IGZO), and indium tin zinc oxide (ITZO).

The encapsulation layer TFE may be disposed over the entire surface of the cathode electrode CE. The encapsulation layer TFE may function to protect components provided under the encapsulation layer TFE from external water or gas. In an embodiment, the encapsulation layer TFE may include a first inorganic encapsulation layer, an organic encapsulation layer, and a second inorganic encapsulation layer that are sequentially stacked in the third direction DR3.

The input sensing layer ISL may be disposed on the display element layer DPL. The input sensing layer ISL may include a sensing electrode YMTL. The sensing electrode YMTL may function to sense an external object such as the hand of the user, a pen, or the like. In an embodiment, the sensing electrode YMTL may overlap the pixel defining layer PDL, and may not overlap the first pixel opening PXO1 and the 2-1-th pixel opening PXO2a.

The light functional layer LFL may include the light blocking layer BM, a first color filter CF1, and a 2-1-th color filter CF2a.

The light blocking layer BM may include the first opening OPN1 and the 2-1-th opening OPN2a. The light blocking layer BM may include light blocking material, and may function to prevent light mixing between adjacent sub-pixels. In an embodiment, the light blocking layer BM may include substantially the same material as the pixel defining layer PDL. In another embodiment, the light blocking layer BM may be provided as a multilayer structure formed by overlapping at least two color filters. For example, the light blocking layer BM between the first color filter CF1 and the 2-1-th color filter CF2a may be formed as a multilayer structure formed by overlapping the first color filter CF1 and the 2-1-th color filter CF2a. In an embodiment, the light blocking layer BM may overlap the sensing electrode YMTL.

The first color filter CF1 may be disposed on the input sensing layer ISL in the first opening OPN1. The first color filter CF1 allows red light to selectively pass therethrough. For example, the first color filter CF1 may be a red color filter.

The 2-1-th color filter CF2a may be disposed on the input sensing layer ISL in the 2-1-th opening OPN2a. The 2-1-th color filter CF2a allows green light to selectively pass therethrough. For example, the 2-1-th color filter CF2a may be a green color filter.

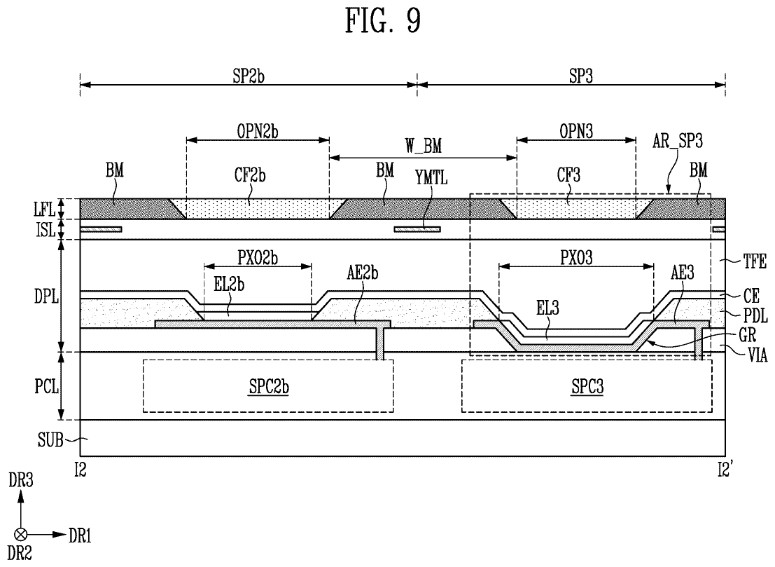

FIG. 9 is a sectional view taken along line I2-I2′ of FIG. 7. In FIG. 9, there are illustrated the 2-2-th sub-pixel SP2b and the third sub-pixel SP3.

Referring to FIGS. 6, 7, and 9, the pixel PXL may include the substrate SUB, the pixel circuit layer PCL, the display element layer DPL, the input sensing layer ISL, and the light functional layer LFL that are sequentially stacked in the third direction DR3.

The pixel circuit layer PCL may include a 2-2-th sub-pixel circuit SPC2b and a third sub-pixel circuit SPC3. The 2-2-th sub-pixel circuit SPC2b may be provided as the sub-pixel circuit SPC (refer to FIG. 2) of the 2-2-th sub-pixel SP2b. The third sub-pixel circuit SPC3 may be provided as the sub-pixel circuit SPC (refer to FIG. 2) of the third sub-pixel SP3.

The display element layer DPL may include the via layer VIA, the 2-2-th anode electrode AE2b, the third anode electrode AE3, the pixel defining layer PDL, a 2-2-th emission layer EL2b, a third emission layer EL3, the cathode electrode CE, and the encapsulation layer TFE.

In an embodiment, in an area where the 2-2-th sub-pixel SP2b is provided, the upper surface of the via layer VIA may be substantially flat. Unlike the foregoing, in an area where the third sub-pixel SP3 is provided, the upper surface of the via layer VIA may not be substantially flat. In the area where the third sub-pixel SP3 is provided, the via layer VIA may include a groove GR recessed in a direction opposite to the third direction DR3. In an embodiment, the groove GR may overlap the third pixel opening PXO3. The groove GR may be formed to expose a portion of the upper surface of the pixel circuit layer PCL.

The 2-2-th anode electrode AE2b may be disposed on the via layer VIA. The 2-2-th anode electrode AE2b may be connected to the 2-2-th sub-pixel circuit SPC2b through a via hole that penetrates the via layer VIA and one or more insulating layers among the insulating layers that constitute the pixel circuit layer PCL. In an embodiment, an upper surface of the 2-2-th anode electrode AE2b may be substantially flat.

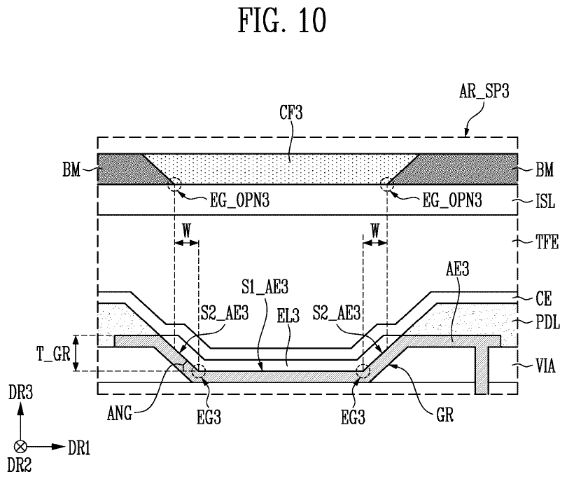

The third anode electrode AE3 may be disposed on the via layer VIA. The third anode electrode AE3 may be connected to the third sub-pixel circuit SPC3 through a via hole that penetrates the via layer VIA and one or more insulating layers among the insulating layers that constitute the pixel circuit layer PCL. A portion of the third anode electrode AE3 may be positioned in the groove GR. Accordingly, a portion of the third anode electrode AE3 may be provided as an inclined surface. Details of the foregoing will be described below with reference to FIG. 10.

The pixel defining layer PDL may be disposed on the via layer VIA, the 2-2-th anode electrode AE2b, and the third anode electrode AE3. The pixel defining layer PDL may include the 2-2-th pixel opening PXO2b that exposes a portion of the 2-2-th anode electrode AE2b, and the third pixel opening PXO3 that exposes a portion of the third anode electrode AE3.

The 2-2-th emission layer EL2b may be disposed on the 2-2-th anode electrode AE2b in the 2-2-th pixel opening PXO2b. The 2-2-th emission layer EL2b may include organic emission material formed to generate green light. In an embodiment, the 2-2-th emission layer EL2b may include substantially the same material as the 2-1-th emission layer EL2a.

The third emission layer EL3 may be disposed on the third anode electrode AE3 in the third pixel opening PXO3. The third emission layer EL3 may include organic emission material formed to generate blue light.

The cathode electrode CE may cover the pixel defining layer PDL, the 2-2-th emission layer EL2b, and the third emission layer EL3. The encapsulation layer TFE may be disposed over the entire surface of the cathode electrode CE.

The input sensing layer ISL may be disposed on the display element layer DPL, and may include the sensing electrode YMTL. In an embodiment, the sensing electrode YMTL may overlap the pixel defining layer PDL, and may not overlap the 2-2-th pixel opening PXO2b and the third pixel opening PXO3.

The light functional layer LFL may include the light blocking layer BM, a 2-2-th color filter CF2b, and a third color filter CF3.

The light blocking layer BM may include the 2-2-th opening OPN2b and the third opening OPN3. The light blocking layer BM may include light blocking material, and may function to prevent light mixing between adjacent sub-pixels. In an embodiment, the light blocking layer BM between the 2-2-th color filter CF2b and the third color filter CF3 may be formed as a multilayer structure formed by overlapping the 2-2-th color filter CF2b and the third color filter CF3. In an embodiment, the light blocking layer BM may overlap the sensing electrode YMTL.

The 2-2-th color filter CF2b may be disposed on the input sensing layer ISL in the 2-2-th opening OPN2b. The 2-2-th color filter CF2b allows green light to selectively pass therethrough. For example, the 2-2-th color filter CF2b may be a green color filter.

The third color filter CF3 may be disposed on the input sensing layer ISL in the third opening OPN3. The third color filter CF3 allows blue light to selectively pass therethrough. For example, the third color filter CF3 may be a blue color filter.

FIG. 10 is an enlarged plan view illustrating a third sub-pixel area AR_SP3 of FIG. 9.

Referring to FIGS. 6, 7, 9, and 10, an enlarged view of the third sub-pixel area AR_SP3 is illustrated.

In an embodiment, a portion of the third anode electrode AE3 may be disposed in the groove GR in an area overlapping the third pixel opening PXO3. Accordingly, the third anode electrode AE3 may include a flat portion S1_AE3 and an inclined portion S2_AE3 around the flat portion S1_AE3 as seen in a plan view. For example, the flat portion S1_AE3 may be circular in a plan view. A center of the flat portion S1_AE3 (i.e., the center of the circle) may be the third center C3 in FIG. 6. The inclined portion S2_AE3 may also be circular in a plan view. In this case, in a plan view, the inclined portion S2_AE3 may surround the flat portion S1_AE3, and an edge of the inclined portion S2_AE3 that is farthest from the substrate SUB may coincide with an edge of the third pixel opening PXO3. As used herein, A and B “coinciding” means A and B are aligned in the third direction, such that they appear as one point or one line in a plan view.

In an embodiment, an acute angle ANG formed by an upper surface of the inclined portion S2_AE3 with respect to a plane parallel to an upper surface of the flat portion S1_AE3 may be approximately 15 degrees or more and approximately 45 degrees or less. In an embodiment, in a sectional view, a distance T_GR in the third direction DR3 between the upper surface of the flat portion S1_AE3 and an upper surface of the third anode electrode AE3 that overlaps the pixel defining layer PDL may be approximately 0.5 micrometers or more and approximately 3 micrometers or less.

In this case, the third emission layer EL3 that is disposed on the third anode electrode AE3 in the third pixel opening PXO3 may have a profile corresponding to the flat portion S1_AE3 and the inclined portion S2_AE3 in a sectional view. In other words, the third emission layer EL3 may have an inclined surface corresponding to the inclined portion S2_AE3, and a flat surface corresponding to the flat portion S1_AE3. As the third emission layer EL3 has the inclined surface, the side visibility of light generated from the third sub-pixel SP3 may be further improved.

In an embodiment, an orthogonal projection of an edge EG_OPN3 of the third opening OPN3 in the third direction DR3 may be located on the inclined portion S2_AE3. In this case, a distance W in the first direction DR1 between the edge EG_OPN3 of the third opening OPN3 and an edge EG3 of the flat portion S1_AE3 may be, for example, approximately 2 micrometers.

Referring again to FIGS. 1 to 10, in the display device DD including the pixel PXL according to an embodiment of the present disclosure, unlike the first and second sub-pixels SP1 and SP2, the third opening radius Y3 in the third sub-pixel SP3 may be less than the third pixel radius X3. Accordingly, as illustrated in FIG. 7, a sufficient width W_BM (refer to FIG. 9) of the light blocking layer BM in the first direction DR1 between the 2-2-th center C2b and the third center C3 may be secured. Likewise, a sufficient width of the light blocking layer BM in the second direction DR2 between the 2-1-th center C2a and the third center C3 may be secured. In this case, if the pixel per inch (ppi) of the pixel PXL increases (i.e., if the resolution is higher), it is possible to secure a sufficient process margin during formation of the light blocking layer BM, which may reduce the difficulty of a process of forming the light blocking layer BM. Furthermore, due to the light blocking layer BM, external light reflected from the cathode electrode CE disposed on the inclined portion S2_AE3 may be effectively blocked, which may enhance the off-state visibility.

In the aforementioned embodiment, the inclined portion S2_AE3 of the third anode electrode AE3 may function to prevent excessive blocking of light emitted from the third emission layer EL3 due to the third opening radius Y3 designed to be relatively small. More specifically, as the third anode electrode AE3 includes the inclined portion S2_AE3, the third emission layer EL3 may have an inclined surface corresponding to the inclined portion S2_AE3. Light emitted from the inclined surface of the third emission layer EL3 may sufficiently pass through the third opening OPN3 having the third opening radius Y3 that is relatively small. In other words, the light output efficiency of the third sub-pixel SP3 may be improved.

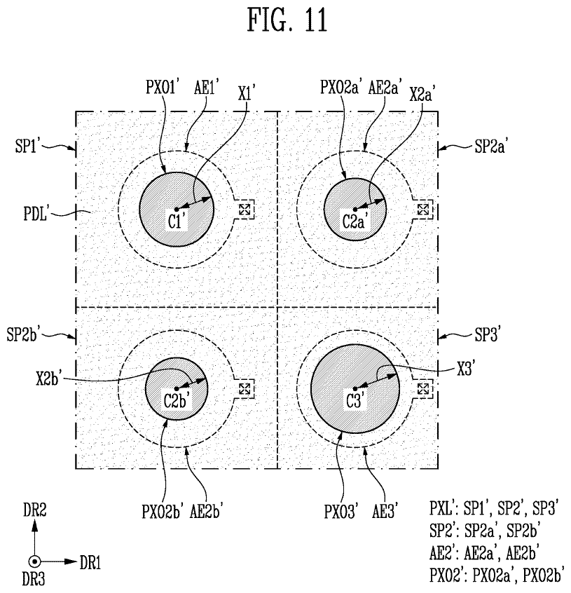

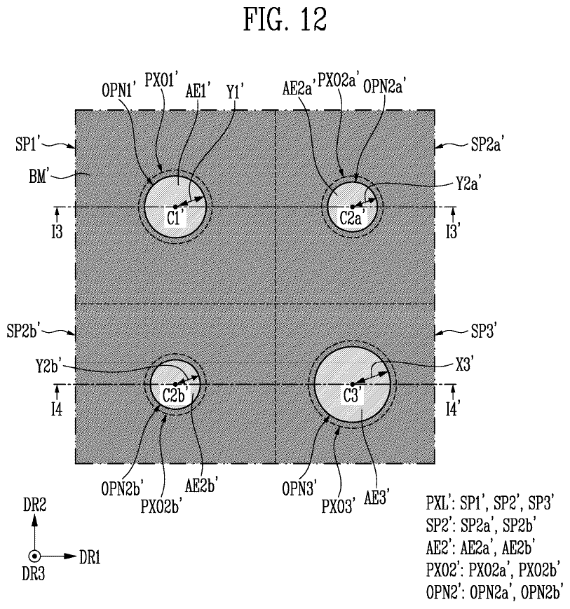

FIGS. 11 and 12 are plan views for describing another embodiment of any one of the pixels included in the display panel DP of FIG. 3.

Referring to FIG. 11, a pixel PXL′ may include sub-pixels SP1′, SP2a′, SP2b′, and SP3′. The first sub-pixel SP1′ is configured to generate light in red, the second color pixel SP2′ (which includes sub-pixels SP2a′ and SP2b′) is configured to generate light in green, and the third sub-pixel SP3′ is configured to generate light in blue.

The first sub-pixel SP1′ may include a first anode electrode AE1′. The first anode electrode AE1′ may be provided as the anode electrode AE (refer to FIG. 2) connected to the sub-pixel circuit SPC (refer to FIG. 2) of the first sub-pixel SP1′.

The second sub-pixel SP2′ may include a second anode electrode AE2′ spaced apart from the first anode electrode AE1′. The second anode electrode AE2′ may be provided as the anode electrode AE connected to the sub-pixel circuit SPC of the second sub-pixel SP2′.

In an embodiment, the second sub-pixel SP2′ may include a 2-1-th sub-pixel SP2a′ and a 2-2-th sub-pixel SP2b′. The 2-1-th sub-pixel SP2a′ may include a 2-1-th anode electrode AE2a′. The 2-1-th anode electrode AE2a′ may be provided as the anode electrode AE connected to the sub-pixel circuit SPC of the 2-1-th sub-pixel SP2a′. The 2-2-th sub-pixel SP2b′ may include a 2-2-th anode electrode AE2b′ spaced apart from the 2-1-th anode electrode AE2a′. The 2-2-th anode electrode AE2b′ may be provided as the anode electrode AE connected to the sub-pixel circuit SPC of the 2-2-th sub-pixel SP2b′.

The third sub-pixel SP3′ may include a third anode electrode AE3′ spaced apart from the first and second anode electrodes AE1′ and AE2′. The third anode electrode AE3′ may be provided as the anode electrode AE connected to the sub-pixel circuit SPC of the third sub-pixel SP3′.

The pixel PXL′ may include a pixel defining layer PDL′. The pixel defining layer PDL′ may include first to third pixel openings PXO1′, PXO2′, and PXO3′ that respectively expose portions of the first to third anode electrodes AE1′, AE2′, and AE3′.

The first pixel opening PXO1′ may expose a portion of the first anode electrode AE1′. The first pixel opening PXO1′ may be circular in a plan view. In this case, a center of the first pixel opening PXO1′ may be a first center C1′. A radius of the first pixel opening PXO1′ may be a first pixel radius X1′.

The second pixel opening PXO2′ may include a 2-1-th pixel opening PXO2a′ and a 2-2-th pixel opening PXO2b′.

The 2-1-th pixel opening PXO2a′ may expose a portion of the 2-1-th anode electrode AE2a′. The 2-1-th pixel opening PXO2a′ may be circular in a plan view. In this case, a center of the 2-1-th pixel opening PXO2a′ may be a 2-1-th center C2a′. A radius of the 2-1-th pixel opening PXO2a′ may be a 2-1-th pixel radius X2a′.

The 2-2-th pixel opening PXO2b′ may expose a portion of the 2-2-th anode electrode AE2b′. The 2-2-th pixel opening PXO2b′ may be circular in a plan view. In this case, a center of the 2-2-th pixel opening PXO2b′ may be a 2-2-th center C2b′. A radius of the 2-2-th pixel opening PXO2b′ may be a 2-2-th pixel radius X2b′.

In an embodiment, the 2-1-th pixel radius X2a′ may be substantially the same as the 2-2-th pixel radius X2b′.

The third pixel opening PXO3′ may expose a portion of the third anode electrode AE3′. The third pixel opening PXO3′ may be circular in a plan view. In this case, a center of the third pixel opening PXO3′ may be a third center C3′. A radius of the third pixel opening PXO3′ may be a third pixel radius X3′.

In an embodiment, the third pixel radius X3′ may be greater than the first pixel radius X1′, may be greater than the 2-1-th pixel radius X2a′, and may be greater than the 2-2-th pixel radius X2b′. The first pixel radius X1′ may be greater than the 2-1-th pixel radius X2a′, and may be greater than the 2-2-th pixel radius X2b′.

Referring to FIG. 12, the pixel PXL′ may include a light blocking layer BM′ disposed on the pixel defining layer PDL′. The light blocking layer BM′ may include first to third openings OPN1′, OPN2′, and OPN3′.

The first opening OPN1′ may be circular in a plan view. In this case, a center of the first opening OPN1′ may correspond to the first center C1′ that is the center of the first pixel opening PXO1′. A radius of the first opening OPN1′ may be a first opening radius Y1′. In an embodiment, the first opening radius Y1′ may be less than the first pixel radius X1′.

The second opening OPN2′ may include a 2-1-th opening OPN2a′ and a 2-2-th opening OPN2b′.

The 2-1-th opening OPN2a′ may be circular in a plan view. In this case, a center of the 2-1-th opening OPN2a′ may correspond to the 2-1-th center C2a′ that is the center of the 2-1-th pixel opening PXO2a′. A radius of the 2-1-th opening OPN2a′ may be a 2-1-th opening radius Y2a′. In an embodiment, the 2-1-th opening radius Y2a′ may be less than the 2-1-th pixel radius X2a′.

The 2-2-th opening OPN2b′ may be circular in a plan view. In this case, a center of the 2-2-th opening OPN2b′ may correspond to the 2-2-th center C2b′ that is the center of the 2-2-th pixel opening PXO2b′. A radius of the 2-2-th opening OPN2b′ may be a 2-2-th opening radius Y2b′. In an embodiment, the 2-2-th opening radius Y2b′ may be less than the 2-2-th pixel radius X2b′.

The third opening OPN3′ may be circular in a plan view. In this case, a center of the third opening OPN3′ may correspond to the third center C3′ that is the center of the third pixel opening PXO3′. A radius of the third opening OPN3′ may be a third opening radius Y3′. In an embodiment, the third opening radius Y3′ may be less than the third pixel radius X3′.

In an embodiment, a difference between the first pixel radius X1′ of the first pixel opening PXO1′ and the first opening radius Y1′ of the first opening OPN1′, a difference between the 2-1-th pixel radius X2a′ of the 2-1-th pixel opening PXO2a′ and the 2-1-th opening radius Y2a′ of the 2-1-th opening OPN2a′, and a difference between the third pixel radius X3′ of the third pixel opening PXO3′ and the third opening radius Y3′ of the third opening OPN3′ may differ from one another. Here, the difference between the 2-1-th pixel radius X2a′ of the 2-1-th pixel opening PXO2a′ and the 2-1-th opening radius Y2a′ of the 2-1-th opening OPN2a′ may be substantially the same as a difference between the 2-2-th pixel radius X2b′ of the 2-2-th pixel opening PXO2b′ and the 2-2-th opening radius Y2b′ of the 2-2-th opening OPN2b′.

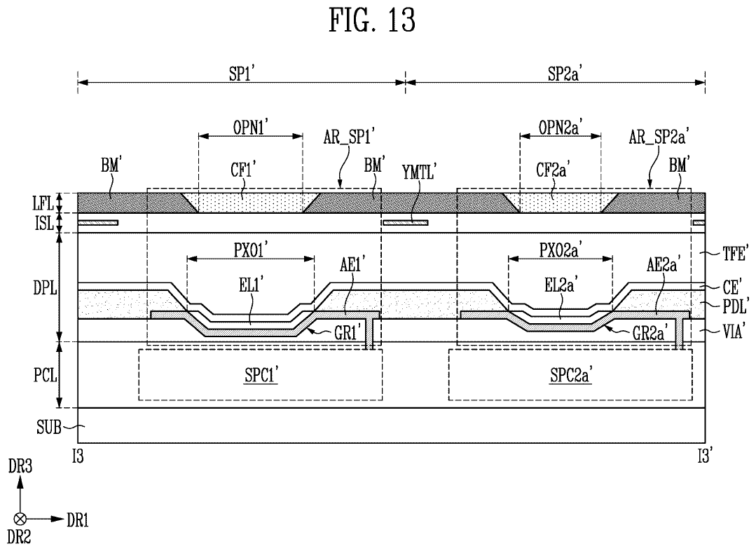

FIG. 13 is a sectional view taken along line I3-I3′ of FIG. 12. In FIG. 13, the first sub-pixel SP1′ and the 2-1-th sub-pixel SP2a′ are illustrated.

Referring to FIGS. 11 to 13, the pixel PXL′ may include the substrate SUB, the pixel circuit layer PCL, the display element layer DPL, the input sensing layer ISL, and the light functional layer LFL that are sequentially stacked in the third direction DR3.

The pixel circuit layer PCL may include a first sub-pixel circuit SPC1′ and a 2-1-th sub-pixel circuit SPC2a′. The first sub-pixel circuit SPC1′ may be provided as the sub-pixel circuit SPC (refer to FIG. 2) of the first sub-pixel SP1′. The 2-1-th sub-pixel circuit SPC2a′ may be provided as the sub-pixel circuit SPC (refer to FIG. 2) of the 2-1-th sub-pixel SP2a′.

The display element layer DPL may include a via layer VIA′, the first anode electrode AE1′, the 2-1-th anode electrode AE2a′, the pixel defining layer PDL′, a first emission layer EL1′, a 2-1-th emission layer EL2a′, the cathode electrode CE′, and an encapsulation layer TFE′.

The via layer VIA′ may be disposed on the pixel circuit layer PCL. The via layer VIA′ may have a single-layer structure or multilayer structure including inorganic material and/or organic material. In an embodiment, in an area where the first sub-pixel SP1′ is provided, the via layer VIA′ may include a first groove GR1′ recessed in a direction opposite to the third direction DR3. The first groove GR1′ may overlap the first pixel opening PXO1′. In an embodiment, in an area where the 2-1-th sub-pixel SP2a′ is provided, the via layer VIA′ may include a 2-1-th groove GR2a′ recessed in a direction opposite to the third direction DR3. The 2-1-th groove GR2a′ may overlap the 2-1-th pixel opening PXO2a′.

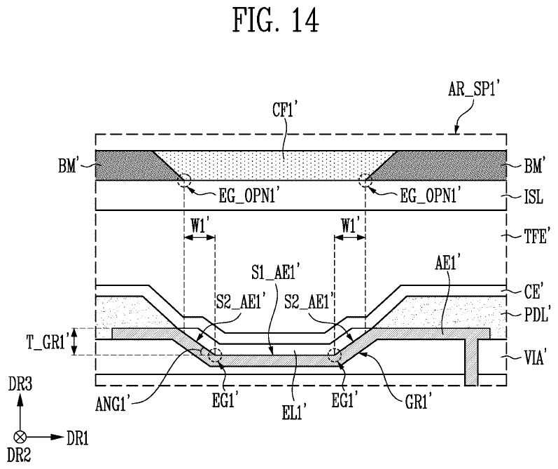

The first anode electrode AE1′ may be disposed on the via layer VIA′. The first anode electrode AE1′ may be connected to the first sub-pixel circuit SPC1′ through a via hole that penetrates the via layer VIA′ and one or more insulating layers among the insulating layers that constitute the pixel circuit layer PCL. A portion of the first anode electrode AE1′ may be positioned in the first groove GR1′. Accordingly, a portion of the first anode electrode AE1′ may be provided as an inclined surface. Details of the foregoing will be described below with reference to FIG. 14.

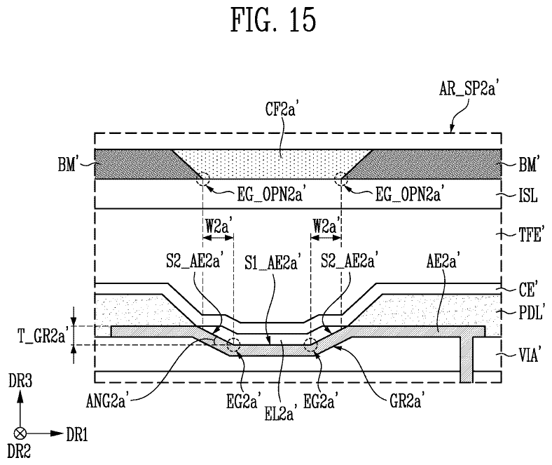

The 2-1-th anode electrode AE2a′ may be disposed on the via layer VIA′. The 2-1-th anode electrode AE2a′ may be connected to the 2-1-th sub-pixel circuit SPC2a′ through a via hole that penetrates the via layer VIA′ and one or more insulating layers among the insulating layers that constitute the pixel circuit layer PCL. A portion of the 2-1-th anode electrode AE2a′ may be positioned in the 2-1-th groove GR2a′. Accordingly, a portion of the 2-1-th anode electrode AE2a′ may be provided as an inclined surface. Details of the foregoing will be described below with reference to FIG. 15.

The pixel defining layer PDL′ may be disposed on the via layer VIA′, the first anode electrode AE1′, and the 2-1-th anode electrode AE2a′. The pixel defining layer PDL′ may include the first pixel opening PXO1′ that exposes a portion of the first anode electrode AE1′, and the 2-1-th pixel opening PXO2a′ that exposes a portion of the 2-1-th anode electrode AE2a′. The pixel defining layer PDL′ may include light blocking material, and may function to prevent light mixing between adjacent sub-pixels. In embodiments, the pixel defining layer PDL′ may include organic material. For example, the pixel defining layer PDL′ may include organic insulating material made of material such as acryl resin, epoxy resin, phenol resin, polyamide resin, polyimide resin, or the like.

The first emission layer EL1′ may be disposed on the first anode electrode AE1′ in the first pixel opening PXO1′. The first emission layer EL1′ may include organic emission material formed to generate red light.

The 2-1-th emission layer EL2a′ may be disposed on the 2-1-th anode electrode AE2a′ in the 2-1-th pixel opening PXO2a′. The 2-1-th emission layer EL2a′ may include organic emission material formed to generate green light.

The cathode electrode CE′ may cover the pixel defining layer PDL′, the first emission layer EL1′, and the 2-1-th emission layer EL2a′. The cathode electrode CE′ may be electrically connected to the second power voltage node VSSN of FIG. 2. The cathode electrode CE′ may be configured to be substantially transparent or translucent to meet a certain light transmittance. For example, the cathode electrode CE′ may include at least one of various transparent conductive materials such as indium tin oxide (ITO), indium zinc oxide (IZO), zinc oxide (ZnO), indium gallium zinc oxide (IGZO), and indium tin zinc oxide (ITZO).

The encapsulation layer TFE′ may be disposed over the entire surface of the cathode electrode CE′. The encapsulation layer TFE′ may function to protect components provided under the encapsulation layer TFE′ from external water or gas. In an embodiment, the encapsulation layer TFE′ may include a first inorganic encapsulation layer, an organic encapsulation layer, and a second inorganic encapsulation layer that are sequentially stacked in the third direction DR3.

The input sensing layer ISL may be disposed on the display element layer DPL. The input sensing layer ISL may include a sensing electrode YMTL′. The sensing electrode YMTL′ may function to sense an external object such as the hand of the user, a pen, or the like. In an embodiment, the sensing electrode YMTL′ may overlap the pixel defining layer PDL′, and may not overlap the first pixel opening PXO1′ and the 2-1-th pixel opening PXO2a′.

The light functional layer LFL may include the light blocking layer BM′, a first color filter CF1′, and a 2-1-th color filter CF2a′.

The light blocking layer BM′ may include a first opening OPN1′ and a second opening OPN2′. The light blocking layer BM′ may include light blocking material, and may function to prevent light mixing between adjacent sub-pixels. In an embodiment, the light blocking layer BM′ may include substantially the same material as the pixel defining layer PDL′. In another embodiment, the light blocking layer BM′ may be provided as a multilayer structure formed by overlapping at least two color filters. For example, the light blocking layer BM′ between the first color filter CF1′ and the 2-1-th color filter CF2a′ may be formed as a multilayer structure formed by overlapping the first color filter CF1′ and the 2-1-th color filter CF2a′. In an embodiment, the light blocking layer BM′ may overlap the sensing electrode YMTL′.

The first color filter CF1′ may be disposed on the input sensing layer ISL in the first opening OPN1′. The first color filter CF1′ allows red light to selectively pass therethrough. For example, the first color filter CF1′ may be a red color filter.

The 2-1-th color filter CF2a′ may be disposed on the input sensing layer ISL in the 2-1-th opening OPN2a′. The 2-1-th color filter CF2a′ allows green light to selectively pass therethrough. For example, the 2-1-th color filter CF2a′ may be a green color filter.

FIG. 14 is an enlarged plan view illustrating a first sub-pixel area AR_SP1′ of FIG. 12.

Referring to FIGS. 11 to 14, an enlarged view of the first sub-pixel area AR_SP1′ is illustrated.

In an embodiment, a portion of the first anode electrode AE1′ may be disposed in the first groove GR1′ in an area overlapping the first pixel opening PXO1′ in a plan view. Accordingly, the first anode electrode AE1′ may include a first flat portion S1_AE1′ and a first inclined portion S2_AE1′ surrounding the first flat portion S1_AE1′ in plan view. For example, the first flat portion S1_AE1′ may be circular in a plan view. A center of the first flat portion S1_AE1′ (i.e., the center of the circle) may be the first center C1′ in FIG. 11. The first inclined portion S2_AE1′ may also be circular in a plan view. In this case, in a plan view, the first inclined portion S2_AE1′ may surround the first flat portion S1_AE1′, and the edge of the first inclined portion S2_AE1′ that is farthest from the substrate SUB may coincide with an edge of the first pixel opening PXO1′.

In an embodiment, a first acute angle ANG1′ formed by an upper surface of the first inclined portion S2_AE1′ with respect to a plane parallel to an upper surface of the first flat portion S1_AE1′ may be approximately 15 degrees or more and approximately 45 degrees or less. In an embodiment, in a sectional view, a first distance T_GR1′ in the third direction DR3 between an upper surface of the first flat portion S1_AE1′ and an upper surface of the first anode electrode AE1′ that overlaps the pixel defining layer PDL′ may be approximately 0.5 micrometers or more and approximately 3 micrometers or less.

In this case, the first emission layer EL1′ that is disposed on the first anode electrode AE1′ in the first pixel opening PXO1′ may have a profile corresponding to the first flat portion S1_AE1′ and the first inclined portion S2_AE1′ in a sectional view. In other words, the first emission layer EL1′ may have an inclined surface corresponding to the first inclined portion S2_AE1′, and a flat surface corresponding to the first flat portion S1_AE1′. As the first emission layer EL1′ has the inclined surface, the side visibility of light generated from the first sub-pixel SP1′ may be further improved.

In an embodiment, an orthogonal projection of an edge EG_OPN1′ of the first opening OPN1′ in the third direction DR3 may be located on the first inclined portion S2_AE1′. In this case, a distance W1′ in the first direction DR1 between the edge EG_OPN1′ of the first opening OPN1′ and an edge EG1′ of the first flat portion S1_AE1′ may be, for example, approximately 3 micrometers.

As the first sub-pixel SP1′ is configured as described above, a sufficient process margin may be secured during formation of the light blocking layer BM′, which may reduce the difficulty of a process of forming the light blocking layer BM′. Furthermore, due to the light blocking layer BM′, external light reflected from the cathode electrode CE′ disposed on the first inclined portion S2_AE1′ may be effectively blocked, which may enhance the off-state visibility. In addition, due to the first inclined portion S2_AE1′ of the first anode electrode AE1′ and the inclined surface of the first emission layer EL1′ corresponding thereto, light emitted from the first emission layer EL1′ may sufficiently pass through the first opening OPN1′. In other words, the light output efficiency of the first sub-pixel SP1′ may be improved.

FIG. 15 is an enlarged plan view illustrating a 2-1-th sub-pixel area AR_SP2a′ of FIG. 12.

Referring to FIGS. 11 to 13 and 15, an enlarged view of the 2-1-th sub-pixel area AR_SP2a′ is illustrated.

In an embodiment, a portion of the 2-1-th anode electrode AE2a′ may be disposed in the 2-1-th groove GR2a′ in an area overlapping the 2-1-th pixel opening PXO2a′. Accordingly, the 2-1-th anode electrode AE2a′ may include a 2-1-th flat portion S1_AE2a′ and a 2-1-th inclined portion S2_AE2a′ surrounding the 2-1-th flat portion S1_AE2a′ in plan view. For example, the 2-1-th flat portion S1_AE2a′ may be circular in a plan view. A center of the 2-1-th flat portion S1_AE2a′ (i.e., the center of the circle) may be the 2-1-th center C2a′ in FIG. 11. The 2-1-th inclined portion S2_AE2a′ may also be circular in a plan view. In this case, in a plan view, the 2-1-th inclined portion S2_AE2a′ may surround the 2-1-th flat portion S1_AE2a′, and an edge of the 2-1-th inclined portion S2_AE2a′ that is farthest from the substrate SUB may coincide with an edge of the 2-1-th pixel opening PXO2a′.

In an embodiment, a 2-1-th acute angle ANG2a′ formed by an upper surface of the 2-1-th inclined portion S2_AE2a′ with respect to a plane parallel to an upper surface of the 2-1-th flat portion S1_AE2a′ may be approximately 15 degrees or more and approximately 45 degrees or less. In an embodiment, the size of the 2-1-th acute angle ANG2a′ may differ from that of the first acute angle ANG1′ (refer to FIG. 14).

In an embodiment, in a sectional view, a 2-1-th distance T_GR2a′ in the third direction DR3 between an upper surface of the 2-1-th flat portion S1_AE2a′ and an upper surface of the 2-1-th anode electrode AE2a′ that overlaps the pixel defining layer PDL′ may be approximately 0.5 micrometers or more and approximately 3 micrometers or less. In an embodiment, the 2-1-th distance T_GR2a′ may differ from the first distance T_GR1′ (refer to FIG. 14).

In this case, the 2-1-th emission layer EL2a′ that is disposed on the 2-1-th anode electrode AE2a′ in the 2-1-th pixel opening PXO2a′ may have a profile corresponding to the 2-1-th flat portion S1_AE2a′ and the 2-1-th inclined portion S2_AE2a′ in a sectional view. In other words, the 2-1-th emission layer EL2a′ may have an inclined surface corresponding to the 2-1-th inclined portion S2_AE2a′, and a flat surface corresponding to the 2-1-th flat portion S1_AE2a′. As the 2-1-th emission layer EL2a′ has the inclined surface, the side visibility of light generated from the 2-1-th sub-pixel SP2a′ may be further improved.

In an embodiment, an orthogonal projection of an edge EG_OPN2a′ of the 2-1-th opening OPN2a′ in the third direction DR3 may be located on the 2-1-th inclined portion S2_AE2a′. In this case, a distance W2a′ in the first direction DR1 between the edge EG_OPN2a′ of the 2-1-th opening OPN2a′ and an edge EG2a′ of the 2-1-th flat portion S1_AE2a′ may be, for example, approximately 3.5 micrometers.

As the 2-1-th sub-pixel SP2a′ is configured as described above, a sufficient process margin may be secured during formation of the light blocking layer BM′, which may reduce the difficulty of a process of forming the light blocking layer BM′. Furthermore, due to the light blocking layer BM′, external light reflected from the cathode electrode CE′ disposed on the 2-1-th inclined portion S2_AE2a′ may be effectively blocked, which may enhance the off-state visibility. In addition, due to the 2-1-th inclined portion S2_AE2a′ of the 2-1-th anode electrode AE2a′ and the inclined surface of the 2-1-th emission layer EL2a′ corresponding thereto, light emitted from the 2-1-th emission layer EL2a′ may sufficiently pass through the 2-1-th opening OPN2a′. In other words, the light output efficiency of the 2-1-th sub-pixel SP2a′ may be improved.

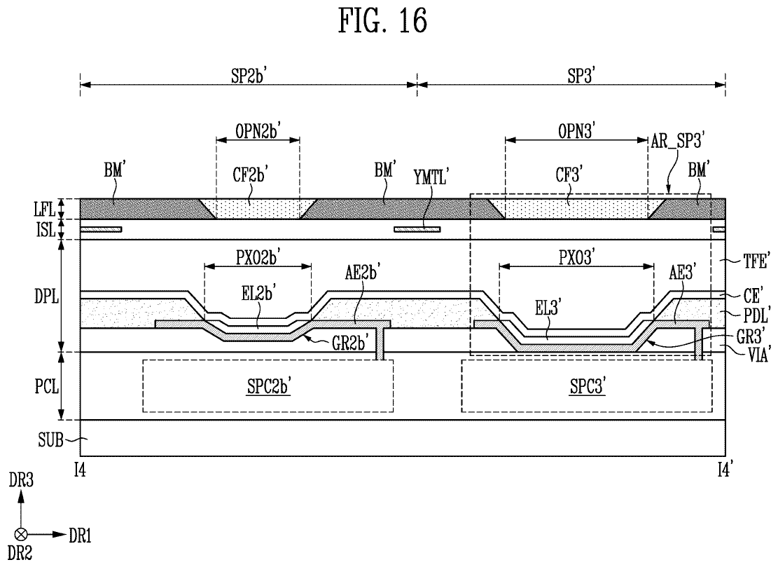

FIG. 16 is a sectional view taken along line I4-I4′ of FIG. 12. In FIG. 16, the 2-2-th sub-pixel SP2b′ and the third sub-pixel SP3′ are illustrated.

Referring to FIGS. 11, 12, and 16, the pixel PXL′ may include the substrate SUB, the pixel circuit layer PCL, the display element layer DPL, the input sensing layer ISL, and the light functional layer LFL that are sequentially stacked in the third direction DR3.

The pixel circuit layer PCL may include a 2-2-th sub-pixel circuit SPC2b′ and a third sub-pixel circuit SPC3′. The 2-2-th sub-pixel circuit SPC2b′ may be provided as the sub-pixel circuit SPC (refer to FIG. 2) of the 2-2-th sub-pixel SP2b′. The third sub-pixel circuit SPC3′ may be provided as the sub-pixel circuit SPC (refer to FIG. 2) of the third sub-pixel SP3′.

The display element layer DPL may include the via layer VIA′, the 2-2-th anode electrode AE2b′, the third anode electrode AE3′, the pixel defining layer PDL′, a 2-2-th emission layer EL2b′, a third emission layer EL3′, the cathode electrode CE′, and the encapsulation layer TFE′.

In an embodiment, in an area where the 2-2-th sub-pixel SP2a′ is provided, the via layer VIA′ may include a 2-2-th groove GR2b′ recessed in a direction opposite to the third direction DR3. The 2-2-th groove GR2b′ may be configured in substantially the same manner as the 2-1-th groove GR2a′ (refer to FIG. 13).

In an embodiment, in an area where the third sub-pixel SP3′ is provided, the via layer VIA′ may include a third groove GR3′ recessed in a direction opposite to the third direction DR3. In an embodiment, the third groove GR3′ may overlap the third pixel opening PXO3′. The third groove GR3′ may be formed to expose a portion of the upper surface of the pixel circuit layer PCL.

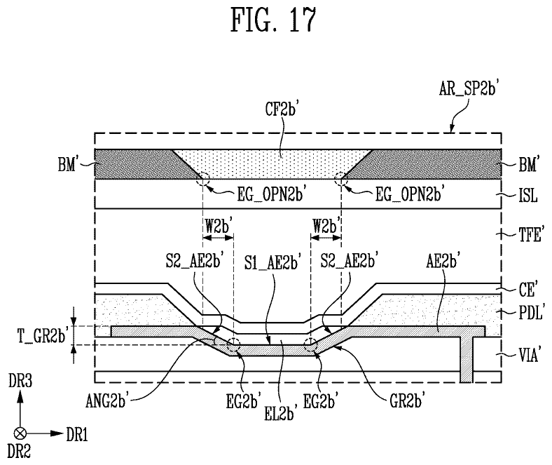

The 2-2-th anode electrode AE2b′ may be disposed on the via layer VIA′. The 2-2-th anode electrode AE2b′ may be connected to the 2-2-th sub-pixel circuit SPC2b′ through a via hole that penetrates the via layer VIA′ and one or more insulating layers among the insulating layers that constitute the pixel circuit layer PCL. A portion of the 2-2-th anode electrode AE2b′ may be positioned in the 2-2-th groove GR2b′. Accordingly, a portion of the 2-2-th anode electrode AE2b′ may be provided as an inclined surface. Details of the foregoing will be described below with reference to FIG. 17.

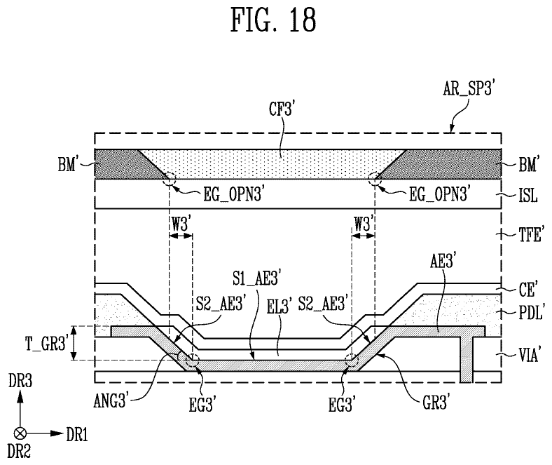

The third anode electrode AE3′ may be disposed on the via layer VIA′. The third anode electrode AE3′ may be connected to the third sub-pixel circuit SPC3′ through a via hole that penetrates the via layer VIA′ and one or more insulating layers among the insulating layers that constitute the pixel circuit layer PCL. A portion of the third anode electrode AE3′ may be positioned in the third groove GR3′. Accordingly, a portion of the third anode electrode AE3′ may be provided as an inclined surface. Details of the foregoing will be described below with reference to FIG. 18.

The pixel defining layer PDL′ may be disposed on the via layer VIA′, the 2-2-th anode electrode AE2b′, and the third anode electrode AE3′. The pixel defining layer PDL′ may include the 2-2-th pixel opening PXO2b′ that exposes a portion of the 2-2-th anode electrode AE2b′, and the third pixel opening PXO3′ that exposes a portion of the third anode electrode AE3′.

The 2-2-th emission layer EL2b′ may be disposed on the 2-2-th anode electrode AE2b′ in the 2-2-th pixel opening PXO2b′. The 2-2-th emission layer EL2b′ may include organic emission material formed to generate green light. In an embodiment, the 2-2-th emission layer EL2b′ may include substantially the same material as the 2-1-th emission layer EL2a′.

The third emission layer EL3′ may be disposed on the third anode electrode AE3′ in the third pixel opening PXO3′. The third emission layer EL3′ may include organic emission material formed to generate blue light.

The cathode electrode CE′ may cover the pixel defining layer PDL′, the 2-2-th emission layer EL2b′, and the third emission layer EL3′. The encapsulation layer TFE′ may be disposed over the entire surface of the cathode electrode CE′.

The light functional layer LFL may include the light blocking layer BM′, a 2-2-th color filter CF2b′, and a third color filter CF3′.

The light blocking layer BM′ may include the 2-2-th opening OPN2b′ and the third opening OPN3′. The light blocking layer BM′ may include light blocking material, and may function to prevent light mixing between adjacent sub-pixels. In an embodiment, the light blocking layer BM′ between the 2-2-th color filter CF2b′ and the third color filter CF3′ may be formed as a multilayer structure formed by overlapping the 2-2-th color filter CF2b′ and the third color filter CF3′. In an embodiment, the light blocking layer BM′ may overlap the sensing electrode YMTL′.

The 2-2-th color filter CF2b′ may be disposed on the input sensing layer ISL in the 2-2-th opening OPN2b′. The 2-2-th color filter CF2b′ allows green light to selectively pass therethrough. For example, the 2-2-th color filter CF2b′ may be a green color filter.

The third color filter CF3′ may be disposed on the input sensing layer ISL in the third opening OPN3′. The third color filter CF3′ allows blue light to selectively pass therethrough. For example, the third color filter CF3′ may be a blue color filter.

FIG. 17 is an enlarged sectional view illustrating a 2-2-th sub-pixel area AR_SP2b′ of FIG. 16.

Referring to FIGS. 11, 12, 16, and 17, an enlarged view of the 2-2-th sub-pixel area AR_SP2b′ is illustrated.

In an embodiment, a portion of the 2-2-th anode electrode AE2b′ may be disposed in the 2-2-th groove GR2b′ in an area overlapping the 2-2-th pixel opening PXO2b′. Accordingly, the 2-2-th anode electrode AE2b′ may include a 2-2-th flat portion S1_AE2b′ and a 2-2-th inclined portion S2_AE2b′ around the 2-2-th flat portion S1_AE2b′. For example, the 2-2-th flat portion S1_AE2b′ may be circular in a plan view. A center of the 2-2-th flat portion S1_AE2b′ (i.e., the center of the circle) may be the 2-2-th center C2b′ in FIG. 11. The 2-2-th inclined portion S2_AE2b′ may also be circular in a plan view. In this case, in a plan view, the 2-2-th inclined portion S2_AE2b′ may surround the 2-2-th flat portion S1_AE2b′, and the edge of the 2-2-th inclined portion S2_AE2b′ that is farthest from the substrate SUB may coincide with the edge of the 2-2-th pixel opening PXO2b′.

In an embodiment, a 2-2-th acute angle ANG2b′ formed by an upper surface of the 2-2-th inclined portion S2_AE2b′ with respect to a plane parallel to an upper surface of the 2-2-th flat portion S1_AE2b′ may be approximately 15 degrees or more and approximately 45 degrees or less. In an embodiment, the size of the 2-2-th acute angle ANG2b′ may be substantially the same as that of the 2-1-th acute angle ANG2a′ (refer to FIG. 15).

In an embodiment, in a sectional view, a 2-2-th distance T_GR2b′ in the third direction DR3 between an upper surface of the 2-2-th flat portion S1_AE2b′ and an upper surface of the 2-2-th anode electrode AE2b′ that overlaps the pixel defining layer PDL′ may be approximately 0.5 micrometers or more and approximately 3 micrometers or less. In an embodiment, the 2-2-th distance T_GR2b′ may be substantially the same as the 2-1-th distance T_GR2a′ (refer to FIG. 15).

In this case, the 2-2-th emission layer EL2b′ that is disposed on the 2-2-th anode electrode AE2b′ in the 2-2-th pixel opening PXO2b′ may have a profile corresponding to the 2-2-th flat portion S1_AE2b′ and the 2-2-th inclined portion S2_AE2b′ in a sectional view. In other words, the 2-2-th emission layer EL2b′ may have an inclined surface corresponding to the 2-2-th inclined portion S2_AE2b′, and a flat surface corresponding to the 2-1-th flat portion S1_AE2b′. As the 2-2-th emission layer EL2b′ has the inclined surface, the side visibility of light generated from the 2-2-th sub-pixel SP2b′ may be further improved.

In an embodiment, an orthogonal projection of an edge EG_OPN2b′ of the 2-2-th opening OPN2b′ in the third direction DR3 may be located on the 2-2-th inclined portion S2_AE2b′. In this case, a distance W2b′ in the first direction DR1 between the edge EG_OPN2b′ of the 2-2-th opening OPN2b′ and an edge EG2b′ of the 2-2-th flat portion S1_AE2b′ may be, for example, approximately 3.5 micrometers.

As the 2-2-th sub-pixel SP2b′ is configured as described above, a sufficient process margin may be secured during formation of the light blocking layer BM′, which may reduce the difficulty of a process of forming the light blocking layer BM′. Furthermore, due to the light blocking layer BM′, external light reflected from the cathode electrode CE′ disposed on the 2-2-th inclined portion S2_AE2b′ may be effectively blocked, which may enhance the off-state visibility. In addition, due to the 2-2-th inclined portion S2_AE2b′ of the 2-2-th anode electrode AE2b′ and the inclined surface of the 2-2-th emission layer EL2b′ corresponding thereto, light emitted from the 2-2-th emission layer EL2b′ may sufficiently pass through the 2-2-th opening OPN2b′. In other words, the light output efficiency of the 2-2-th sub-pixel SP2b′ may be improved.

FIG. 18 is an enlarged sectional view illustrating a third sub-pixel area AR_SP3′ of FIG. 16.

Referring to FIGS. 11, 12, 16, and 18, an enlarged view of the third sub-pixel area AR_SP3′ is illustrated.

In an embodiment, a portion of the third anode electrode AE3′ may be disposed in the third groove GR3′ in an area overlapping the third pixel opening PXO3′. Accordingly, the third anode electrode AE3′ may include a third flat portion S1_AE3′ and a third inclined portion S2_AE3′ surrounding the third flat portion S1_AE3′ in plan view. For example, the third flat portion S1_AE3′ may be circular in a plan view. A center of the third flat portion S1_AE3′ (i.e., the center of the circle) may be the third center C3′ in FIG. 11. The third inclined portion S2_AE3′ may also be circular in a plan view. In this case, in a plan view, the third inclined portion S2_AE3′ may surround the third flat portion S1_AE3′, and the edge of the third inclined portion S2_AE3′ that is farthest from the substrate SUB may coincide with an edge of the third pixel opening PXO3′.

In an embodiment, a third acute angle ANG3′ formed by an upper surface of the third inclined portion S2_AE3′ with respect to a plane parallel to an upper surface of the third flat portion S1_AE3′ may be approximately 15 degrees or more and approximately 45 degrees or less. In an embodiment, the size of the third acute angle ANG3′ may differ from that of the first acute angle ANG1′ (refer to FIG. 14), and may also differ from the 2-1-th acute angle ANG2a′ (refer to FIG. 15).

In an embodiment, in a sectional view, a third distance T_GR3′ in the third direction DR3 between an upper surface of the third flat portion S1_AE3′ and an upper surface of the third anode electrode AE3′ that overlaps the pixel defining layer PDL′ may be approximately 0.5 micrometers or more and approximately 3 micrometers or less. In an embodiment, the third distance T_GR3′ may differ from the first distance T_GR1′ (refer to FIG. 14), and may also differ from the 2-1-th distance T_GR2a′ (refer to FIG. 15).

In this case, the third emission layer EL3′ that is disposed on the third anode electrode AE3′ in the third pixel opening PXO3′ may have a profile corresponding to the third flat portion S1_AE3′ and the third inclined portion S2_AE3′ in a sectional view. In other words, the third emission layer EL3′ may have an inclined surface corresponding to the third inclined portion S2_AE3′, and a flat surface corresponding to the third flat portion S1_AE3′. As the third emission layer EL3′ has the inclined surface, the side visibility of light generated from the third sub-pixel SP3′ may be further improved.

In an embodiment, an orthogonal projection of an edge EG_OPN3′ of the third opening OPN3′ in the third direction DR3 may be located on the third inclined portion S2_AE3′. In this case, a distance W3′ in the first direction DR1 between the edge EG_OPN3′ of the third opening OPN3′ and an edge EG3′ of the third flat portion S1_AE3′ may be, for example, approximately 2 micrometers.

As the third sub-pixel SP3′ is configured as described above, a sufficient process margin may be secured during formation of the light blocking layer BM′, which may reduce the difficulty of a process of forming the light blocking layer BM′. Furthermore, due to the light blocking layer BM′, external light reflected from the cathode electrode CE′ disposed on the third inclined portion S2_AE3′ may be effectively blocked, which may enhance the off-state visibility. In addition, due to the third inclined portion S2_AE3′ of the third anode electrode AE3′ and the inclined surface of the third emission layer EL3′ corresponding thereto, light emitted from the third emission layer EL3′ may sufficiently pass through the third opening OPN3′. In other words, the light output efficiency of the third sub-pixel SP3′ may be improved.

A display device in accordance with embodiments of the present disclosure may include first, second, and third anode electrodes disposed to be spaced apart from one another, a pixel defining layer including first to third pixel openings, and a light blocking layer including first to third openings.

A radius of the third opening may be less than a radius of the third pixel opening. As such, since the radius of the third opening is designed to be small, a sufficient process margin during formation of the light blocking layer may be secured. Therefore, the process difficulty of forming the light blocking layer may be reduced, and the degree of design freedom of the display device may be improved.

The third anode electrode may include, in an area overlapping the third pixel opening in a plan view, a flat portion and an inclined portion around the flat portion. As the third anode electrode includes the inclined portion, a third emission layer disposed on the third anode electrode may have an inclined surface corresponding to the inclined portion. Light emitted from the inclined surface of the third emission layer may pass through the third opening having a small radius. Hence, the light output efficiency may be enhanced.

A display device according to an embodiment is applicable to various types of electronic devices. In an embodiment, an electronic device includes the above-described display device and may further include other modules or devices having additional functions in addition to the display device.

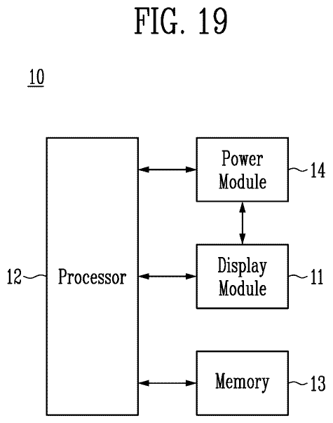

FIG. 19 is a block diagram of an electronic device according to an embodiment. Referring to FIG. 19, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

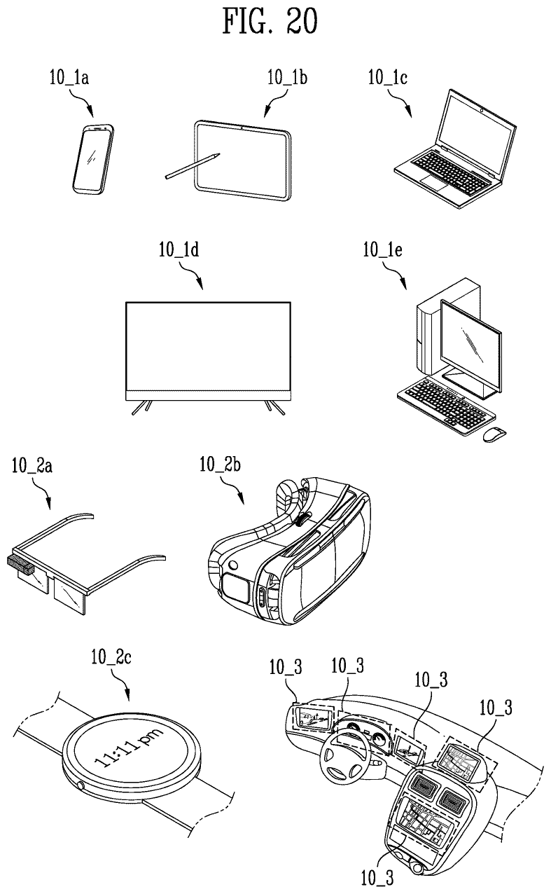

FIG. 20 shows schematic views of various embodiments of an electronic device.

Referring to FIG. 20, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

While embodiments have been described above, those skilled in the art will appreciate that various modifications, additions and substitutions are possible, without departing from the scope and spirit of the present disclosure claimed in the appended claims.

What is claimed is:

1. A display device, comprising:
a first, a second, and a third anode electrodes spaced apart from one another;
a pixel defining layer including a first, a second, and a third pixel openings disposed on the first, the second, and the third anode electrodes, each of the first, the second, and the third pixel openings having a circular shape in a plan view, the first to third pixel openings extending to portions of the first, the second, and the third anode electrodes, respectively;
a first, a second, and a third emission layers disposed on the first, the second, and the third anode electrodes in the first, the second, and the third pixel openings, respectively;
a cathode electrode covering the pixel defining layer and the first, the second, and the third emission layers; and
a light blocking layer disposed on the cathode electrode and including a first opening, a second opening, and a third opening each having a circular shape in a plan view,
wherein the third anode electrode includes, in an area overlapping the third pixel opening, a flat portion and an inclined portion around the flat portion,
wherein centers of the first pixel opening, the second pixel opening, and the third pixel opening coincide with centers of the first opening, the second opening, and the third opening, respectively, and
wherein a radius of the third opening is smaller than a radius of the third pixel opening.

2. The display device according to claim 1,
wherein a radius of the first opening is greater than a radius of the first pixel opening, and
wherein a radius of the second opening is greater than a radius of the second pixel opening.

3. The display device according to claim 1, wherein the radius of the third pixel opening is greater than a radius of the first pixel opening and a radius of the second pixel opening.

4. The display device according to claim 3, wherein the radius of the first pixel opening is greater than the radius of the second pixel opening.

5. The display device according to claim 1, wherein a difference between a radius of the first opening and a radius of the first pixel opening is equal to a difference between a radius of the second opening and a radius of the second pixel opening.

6. The display device according to claim 1, wherein in a cross-sectional view, an acute angle formed by an upper surface of the inclined portion with respect to a plane parallel to an upper surface of the flat portion is about 15 degrees or more and about 45 degrees or less.

7. The display device according to claim 1, wherein in a cross-sectional view, a distance in a thickness direction between an upper surface of the third anode electrode overlapping a flat surface of the pixel defining layer and an upper surface of the flat portion is about 0.5 micrometers or more and about 3 micrometers or less.

8. The display device according to claim 1, wherein in a cross-sectional view, an orthogonal projection of an edge of the third opening in a thickness direction is positioned on the inclined portion.

9. The display device according to claim 1, further comprising:
a first color filter disposed in the first opening;
a second color filter disposed in the second opening; and
a third color filter disposed in the third opening.

10. A display device, comprising:
a first anode electrode including a first flat portion and a first inclined portion surrounding the first flat portion;
a second anode electrode including a second flat portion and a second inclined portion surrounding the second flat portion;
a third anode electrode including a third flat portion and a third inclined portion surrounding the third flat portion;
a pixel defining layer including a first pixel opening exposing the first flat portion and the first inclined portion and having a circular shape in a plan view, a second pixel opening exposing the second flat portion and the second inclined portion and having a circular shape in a plan view, and a third pixel opening exposing the third flat portion and the third inclined portion and having a circular shape in a plan view;
first, second, and third emission layers disposed on the first, the second, and the third anode electrodes in the first, the second, and the third pixel openings, respectively;
a cathode electrode covering the pixel defining layer and the first, the second, and the third emission layers; and
a light blocking layer disposed on the cathode electrode and including a first opening, a second opening, and a third opening each having a circular shape in a plan view,
wherein centers of the first pixel opening, the second pixel opening, and the third pixel opening coincide with centers of the first opening, the second opening, and the third opening, respectively.

11. The display device according to claim 10,
wherein a radius of the first opening is less than a radius of the first pixel opening,
wherein a radius of the second opening is less than a radius of the second pixel opening, and
wherein a radius of the third opening is less than a radius of the third pixel opening.

12. The display device according to claim 10, wherein in a plan view, a first difference between a radius of the first pixel opening and a radius of the first opening, a second difference between a radius of the second pixel opening and a radius of the second opening, and a third difference between the third pixel opening and a radius of the third opening differ from one another.

13. The display device according to claim 10, wherein in a plan view, a radius of the third pixel opening is greater than a radius of the first pixel opening and a radius of the second pixel opening.

14. The display device according to claim 13, wherein the radius of the first pixel opening is greater than the radius of the second pixel opening.

15. The display device according to claim 10,
wherein in a cross-sectional view, an orthogonal projection of an edge of the first opening in a thickness direction is positioned on the first inclined portion,
wherein in a cross-sectional view, an orthogonal projection of an edge of the second opening in the thickness direction is positioned on the second inclined portion, and
wherein in a cross-sectional view, an orthogonal projection of an edge of the third opening in the thickness direction is positioned on the third inclined portion.

16. The display device according to claim 10, wherein in a cross-sectional view, a first acute angle between an upper surface of the first inclined portion and a plane parallel to an upper surface of the first flat portion, a second acute angle between an upper surface of the second inclined portion and a plane parallel to an upper surface of the second flat portion, and a third acute angle between an upper surface of the third inclined portion with respect to a plane parallel to an upper surface of the third flat portion each are about 15 degrees or more and about 45 degrees or less.

17. The display device according to claim 16, wherein in a cross-sectional view, the first acute angle, the second acute angle, and the third acute angle differ from one another.

18. The display device according to claim 10, wherein in a cross-sectional view, each of a first distance in a thickness direction between an upper surface of the first anode electrode overlapping the pixel defining layer and an upper surface of the first flat portion, a second distance in the thickness direction between an upper surface of the second anode electrode overlapping the pixel defining layer and an upper surface of the second flat portion, and a third distance in the thickness direction between an upper surface of the third anode electrode overlapping the pixel defining layer and an upper surface of the third flat portion is at least about 0.5 micrometers and not more and about 3 micrometers.

19. The display device according to claim 18, wherein in a cross-sectional view, the first distance, the second distance, and the third distance differ from one another.

20. An electronic device, comprising:
a display device to display an image, wherein the display device comprises:
a first, a second, and a third anode electrodes spaced apart from one another;
a pixel defining layer including a first, a second, and a third pixel openings each having a circular shape in a plan view, the first, the second, and the third pixel openings extending to portions of the first, the second, and the third anode electrodes, respectively;
a first, a second, and a third emission layers disposed on the first, the second, and the third anode electrodes in the first, the second, and the third pixel openings, respectively;
a cathode electrode covering the pixel defining layer and the first, the second, and the third emission layers; and
a light blocking layer disposed on the cathode electrode, and including a first opening, a second opening, and a third opening each having a circular shape in a plan view,
wherein the third anode electrode includes, in an area overlapping the third pixel opening, a flat portion and an inclined portion around the flat portion,
wherein centers of the first pixel opening, the second pixel opening, and the third pixel opening coincide with centers of the first opening, the second opening, and the third opening, respectively, and
wherein a radius of the third opening is smaller than a radius of the third pixel opening.
